(19) United States
(12) Patent Application Publication
(10) Pub. No.: US 2025/0336671 A1
(43) Pub. Date: Oct. 30, 2025

(54) METHOD AND SYSTEM FOR MANUFACTURING A GERMANIUM-BASED MEMBRANE, AND GERMANIUM-BASED SUBSTRATE

(71) Applicant: SOCIETE DE COMMERCIALISATION DES PRODUITS DE LA RECHERCHE APPLIQUÉE SOCPRA SCIENCES ET GÉNIE S.E.C., Sherbrooke (CA)

(72) Inventors: Tadeáš HANUŠ, Sherbrooke (CA); Bouraoui ILAHI, Sherbrooke (CA); Abderraouf BOUCHERIF, Sherbrooke (CA)

(21) Appl. No.: 18/647,018

(22) Filed: Apr. 26, 2024

(51) Int. Cl. H01L 21/02; C30B 25/08; C30B 25/20; H01L 29/16

(52) U.S. Cl. CPC H01L 21/02532; C30B 25/08; C30B 25/20; H01L 21/02381; H01L 21/02428; H10D 62/83

(57) ABSTRACT

The method of manufacturing a germanium-based membrane generally has: at a first temperature, forming a non-porous layer of a germanium-based material on a porous layer of a first germanium substrate, the first temperature below a reorganization temperature of the porous layer of the first germanium substrate; and uncoupling the non-porous layer of the germanium-based material from the porous layer of the first germanium substrate thereby obtaining the germanium-based membrane and a second germanium substrate comprising porous germanium remnants including germanium crystallites.

### FIELD

The improvements generally relate to germanium-based membranes and more specifically to the manufacturing of such germanium-based membranes using porous germanium substrates.

### BACKGROUND

Semiconductor-based freestanding membranes (FSM) have recently emerged as a highly promising area of advanced materials research. Their unique properties, such as lightweight and flexibility, make them attractive for a wide range of device applications. Although existing FSM manufacturing techniques are satisfactory to a certain degree, there always remains room for improvement, especially in producing high-quality FSM from elemental semiconductor materials such as germanium (Ge).

### SUMMARY

In recent years, high-quality FSM made of functional materials have become central to the rapidly expanding frontiers of nanoscience and technology. Group IV, III-V and III-N semiconducting membranes in particular have high potential for applications such as stretchable on-skin electronic, vertically stacked light-emitting diodes (LEDs), and flexible photodetectors, to name only a few examples. Indeed, FSM offer an extra degree of freedom for implementations that cannot be obtained by conventional techniques such as hetero-integration of dissimilar materials with high lattice mismatch in crystalline structures. In addition to being lightweight and flexible, FSM can allow for various materials to be stacked on top of each other, enabling easy coupling of physical properties between dissimilar materials. Furthermore, the use of FSM provides significant cost savings for the device production, especially for materials with prices an order of magnitude greater than that of silicon, when compared to bulky wafers. In this context, germanium-based FSM particularly attract attention for their applications in high-performance optoelectronics and high-speed telecommunication devices such as wave guides, THz transmission, photodetectors and lasers as well as for their biocompatibility. However, the fabrication of high-quality germanium-based FSM remains challenging for a variety of reasons.

For instance, remote epitaxy has shown tremendous potential for fabrication of III-N and III-V semiconductor compounds FSM, and for other materials such as complex oxides, perovskites, metals, and the like. Nevertheless, remote epitaxy is based on ionic, polar interaction between the epilayer and the underling substrate through the graphene interface, prohibiting its application to nonpolar materials such as Ge. Despite achieving significant advancements, the widespread adoption of Ge-based FSM is still hindered by various obstacles including process complexity and high cost, substrates damage and/or contamination issues.

For example, material deposition on porous Ge (PGe) substrate has demonstrated high potential to produce lightweight solar cells. So far, successful epitaxy on PGe substrates is mainly based on high temperature annealing steps either before or during the material deposition, triggering the thermal reorganization of the porous layer. For instance, PGe with sponge-like morphology show a strong temperature dependence, inducing the formation of large pillar structures, while losing its intrinsic PGe properties and complicating the reconditioning process. The membrane uncoupling is achieved through the mechanically weak interface, formed by nano- to microscale-sized pillars. To this date, a variety of lift-off techniques allowing the production of single-crystalline Ge FSM and the reuse of wafers have already been reported, namely epitaxial lift-off (ELO), mechanical spalling, smart cut method, growth on nanopatterned graphene, Germanium-on-nothing (GON) or porous lift-off. After FSM uncoupling, the substrate surface contains broken pillars with various sizes whose reconditioning for multiple reuses requires either conventional chemical mechanical polishing (CMP) treatment or wet chemical etching over several microns, which can be undesirable. Despite the significant improvements high-temperature material deposition on porous Ge may bring, it was found that this technique still leaves room for further improvements both in terms of cost and Ge consumption during the reconditioning process.

In one aspect, this disclosure presents a method of manufacturing easily uncoupleable germanium-based FSM on PGe substrates using low temperature deposition. The proposed method is based on the preservation of the porous structure's integrity through the membrane deposition process, which is achieved by depositing, at a temperature below a porous germanium reorganization temperature, a non-porous layer of germanium-based material on a porous layer of germanium. It was found that the proposed method is applicable regardless of the PGe porosity and thickness while ensuring easy substrate preparation for multiple reuses. PGe substrates thus offer a wide range of morphologies and physical properties, that can be directly used in the Ge-based FSM fabrication by deposition on an unreconstructed porous structure.

In accordance with a first aspect of the present disclosure, there is provided a method of manufacturing a germanium-based membrane, the method comprising: at a first temperature, forming a non-porous layer of a germanium-based material on a porous layer of a first germanium substrate, the first temperature below a reorganization temperature of the porous layer of the first germanium substrate; and uncoupling the non-porous layer of the germanium-based material from the porous layer of the first germanium substrate thereby obtaining the germanium-based membrane and a second germanium substrate comprising porous germanium remnants including germanium crystallites.

Further in accordance with the first aspect of the present disclosure, when said forming can for example be performed within a vacuum environment, the first temperature ranges between 25° C. and 325° C., preferably between 100° C. and 325° C., and most preferably between 200° C. and 325° C.

Still further in accordance with the first aspect of the present disclosure, after said forming, the porous layer of the first germanium substrate can for example have a plurality of pore walls extending between the first germanium substrate and the non-porous layer, the pore walls having a morphology similar to an initial morphology of pore walls of the porous layer prior to said forming.

Still further in accordance with the first aspect of the present disclosure, the germanium crystallites of the porous germanium remnants can for example have a dimension ranging between 1 nm and 19 nm.

Still further in accordance with the first aspect of the present disclosure, the method can for example further comprise removing the porous germanium remnants from the second germanium substrate.

Still further in accordance with the first aspect of the present disclosure, said removing can for example comprise the steps of: oxidizing the germanium crystallites of the porous germanium remnants using an oxidizing agent to oxidize crystallites of the porous germanium remnants; and subsequently to said oxidizing, etching remaining porous germanium remnants using a chemically active etchant.

Still further in accordance with the first aspect of the present disclosure, the oxidizing agent can for example be hydrogen peroxide (H₂O₂) and the chemically active etchant can for example be hydrofluoric acid (HF).

Still further in accordance with the first aspect of the present disclosure, the first germanium substrate and the second germanium substrate can for example comprise porous germanium remnants having a porosity ranging between 40 and 80%.

Still further in accordance with the first aspect of the present disclosure, said removing leaves the germanium with a surface roughness below 1 nm.

Still further in accordance with the first aspect of the present disclosure, the germanium-based material can for example be monocrystalline germanium.

Still further in accordance with the first aspect of the present disclosure, the germanium-based material can for example be a germanium-based alloy including at least one group IV element.

Still further in accordance with the first aspect of the present disclosure, the at least one group IV element can for example be selected from a group consisting of: silicon (Si), tin (Sn), and lead (Pb).

Still further in accordance with the first aspect of the present disclosure, the germanium-based material can for example be doped germanium.

In accordance with a second aspect of the present disclosure, there is provided a system for manufacturing a germanium-based membrane, the system comprising: a membrane formation device forming a non-porous layer of a germanium-based material on a porous layer of a first germanium substrate at a first temperature below a reorganization temperature of the porous layer of the first germanium substrate; and an uncoupling device uncoupling the non-porous layer of the germanium-based material from the porous layer of the first germanium substrate thereby obtaining the germanium-based membrane and a second germanium substrate comprising porous germanium remnants including germanium crystallites.

Further in accordance with the second aspect of the present disclosure, when said membrane formation device can for example include a vacuum chamber inside which said forming is performed, the first temperature ranges between 25° C. and 325° C., preferably between 100° C. and 325° C., and most preferably between 200° C. and 325° C.

Still further in accordance with the second aspect of the present disclosure, after said forming, the porous layer of the first germanium substrate can for example have a plurality of pore walls extending between the first germanium substrate and the non-porous layer, the pore walls having a morphology similar to an initial morphology of pore walls of the porous layer prior to said forming.

Still further in accordance with the second aspect of the present disclosure, the germanium crystallites of the porous germanium remnants can for example have a dimension ranging between 1 nm and 19 nm.

Still further in accordance with the second aspect of the present disclosure, the system can for example further comprise a cleaning device removing porous germanium remnants from the second germanium substrate.

Still further in accordance with the second aspect of the present disclosure, the cleaning device can for example perform a step of oxidizing the germanium crystallites of the porous germanium remnants using an oxidizing agent; and subsequently to said oxidizing, a step of etching remaining porous germanium remnants using a chemically active etchant.

Still further in accordance with the second aspect of the present disclosure, the germanium-based material can for example be a germanium-based alloy including at least one group IV element selected from a group consisting of: silicon (Si), tin (Sn), and lead (Pb).

In accordance with a third aspect of the present disclosure, there is provided a germanium-based substrate comprising: a planar body of germanium; and a plurality of porous germanium remnants made integral to the planar body of germanium and protruding from the planar body of germanium, the porous germanium remnants comprising germanium crystallites having a dimension ranging between 1 nm and 19 nm.

In some aspects of the present disclosure, the aspects described herein can be applied to semiconductor materials that may or may not include germanium-based materials. Indeed, as other types of semiconductor materials have been known to exhibit porous structure reorganization with rising temperature, depositing a non-porous layer of semiconductor material on a porous layer of semiconductor material while keeping the temperature below the reorganization temperature of the porous layer of semiconductor material can be advantageous in at least some circumstances.

In accordance with a fourth aspect of the present disclosure, there is provided a method of manufacturing a semiconductor membrane, the method comprising: at a first temperature, forming a non-porous layer of a semiconductor material on a porous layer of a first semiconductor substrate, the first temperature below a reorganization temperature of the porous layer of the first semiconductor substrate; and uncoupling the non-porous layer of the semiconductor material from the porous layer of the first semiconductor substrate thereby obtaining the semiconductor membrane and a second semiconductor substrate comprising porous semiconductor remnants including semiconductor crystallites.

Further in accordance with the fourth aspect of the present disclosure, when said forming is performed within a vacuum environment, the first temperature ranges between 25° C. and 325° C., preferably between 100° C. and 325° C., and most preferably between 200° C. and 325° C.

Still further in accordance with the fourth aspect of the present disclosure, when the porous layer includes porous silicon (Si), the reorganization temperature ranges between 475° C. and 525° C.

Still further in accordance with the fourth aspect of the present disclosure, when the porous layer includes porous gallium nitride (GaN), the reorganization temperature ranges between 875° C. and 925° C.

Still further in accordance with the fourth aspect of the present disclosure, when the porous layer includes porous indium phosphide (InP), the reorganization temperature ranges between 425° C. and 475° C.

Still further in accordance with the fourth aspect of the present disclosure, when the porous layer includes porous gallium arsenide (GaAs), the reorganization temperature ranges between 475° C. and 525° C.

Still further in accordance with the fourth aspect of the present disclosure, after said forming, the porous layer of the first semiconductor substrate has a plurality of pore walls extending between the first semiconductor substrate and the non-porous layer, the pore walls having a morphology similar to an initial morphology of pore walls of the porous layer prior to said forming.

Still further in accordance with the fourth aspect of the present disclosure, the semiconductor crystallites of the porous semiconductor remnants having a dimension ranging between 1 nm and 19 nm.

Still further in accordance with the fourth aspect of the present disclosure, the method can for example further comprise removing the porous semiconductor remnants from the second semiconductor substrate.

Still further in accordance with the fourth aspect of the present disclosure, said removing can for example comprise the steps of: oxidizing the semiconductor crystallites of the porous semiconductor remnants using an oxidizing agent, and subsequently to said oxidizing, etching remaining porous semiconductor remnants using a chemically active etchant.

Still further in accordance with the fourth aspect of the present disclosure, the oxidizing agent is hydrogen peroxide (H₂O₂) and the chemically active etchant is hydrofluoric acid (HF).

Still further in accordance with the fourth aspect of the present disclosure, the first semiconductor substrate and the second semiconductor substrate can for example comprise porous semiconductor remnants having a porosity ranging between 40 and 80%.

Still further in accordance with the fourth aspect of the present disclosure, said removing leaves the second semiconductor substrate with a surface roughness below 1 nm.

Still further in accordance with the fourth aspect of the present disclosure, the semiconductor material is a monocrystalline semiconductor.

Still further in accordance with the fourth aspect of the present disclosure, the semiconductor material is a semiconductor alloy including at least one group IV element.

Still further in accordance with the fourth aspect of the present disclosure, the at least one group IV element is selected from a group consisting of: silicon (Si), tin (Sn), and lead (Pb).

Still further in accordance with the fourth aspect of the present disclosure, the semiconductor material is a doped semiconductor.

In accordance with a fifth aspect of the present disclosure, there is provided a system for manufacturing a semiconductor membrane, the system comprising: a membrane formation device forming a non-porous layer of a semiconductor material on a porous layer of a first semiconductor substrate at a first temperature below a reorganization temperature of the porous layer of the first semiconductor substrate; and an uncoupling device uncoupling the non-porous layer of the semiconductor material from the porous layer of the first semiconductor substrate thereby obtaining the semiconductor membrane and a second semiconductor substrate comprising porous semiconductor remnants including semiconductor crystallites.

Further in accordance with the fifth aspect of the present disclosure, when said membrane formation device includes a vacuum chamber inside which said forming is performed, the first temperature ranges between 25° C. and 325° C., preferably between 100° C. and 325° C., and most preferably between 200° C. and 325° C.

Still further in accordance with the fifth aspect of the present disclosure, after said forming, the porous layer of the first semiconductor substrate has a plurality of pore walls extending between the first semiconductor substrate and the non-porous layer, the pore walls having a morphology similar to an initial morphology of pore walls of the porous layer prior to said forming.

Still further in accordance with the fifth aspect of the present disclosure, the semiconductor crystallites of the porous semiconductor remnants can for example have a dimension ranging between 1 nm and 19 nm.

Still further in accordance with the fifth aspect of the present disclosure, the system further comprising a cleaning device removing porous semiconductor remnants from the second semiconductor substrate.

Still further in accordance with the fifth aspect of the present disclosure, the cleaning device performs a step of oxidizing the semiconductor crystallites of the porous semiconductor remnants using an oxidizing agent, and subsequently to said oxidizing, etching remaining porous semiconductor remnants using a chemically active etchant.

Still further in accordance with the fifth aspect of the present disclosure, the semiconductor material is a semiconductor alloy including at least one group IV element selected from a group consisting of: silicon (Si), tin (Sn), and lead (Pb).

In accordance with a sixth aspect of the present disclosure, there is provided a semiconductor substrate comprising: a planar body of semiconductor; and a plurality of porous semiconductor remnants made integral to the planar body of semiconductor and protruding from the planar body of semiconductor, the porous semiconductor remnants comprising semiconductor crystallites having a dimension ranging between 1 nm and 19 nm.

Although the methods and systems described herein can be broadly applied to any suitable semiconductor materials, most of the embodiments presented in this disclosure involve germanium-based materials for ease of reading.

The term “uncoupling force” is meant to encompass any type of force that would be applied on the germanium-based membrane and/or to the germanium substrate to uncouple the membrane from the germanium substrate. The uncoupling force can be a pulling force pulling the germanium-based membrane away from the germanium substrate, and/or a shearing force directed along a plane extending between the germanium-based membrane and the germanium substrate, to name a few examples.

The term “coupling force” is meant to encompass the force with which the membrane is coupled to the germanium substrate. Typically, to uncouple the membrane from the substrate, an uncoupling force corresponding to or exceeding the coupling force has to be applied.

All technical implementation details and advantages described with respect to a particular aspect of the present invention are self-evidently mutatis mutandis applicable for all other aspects of the present invention.

Many further features and combinations thereof concerning the present improvements will appear to those skilled in the art following a reading of the instant disclosure.

### DESCRIPTION OF THE FIGURES

In the figures,

FIG. 1 is a schematic view of an example of a system for manufacturing a germanium-based membrane, in accordance with one or more embodiments;

FIG. 2 is a flow chart of an example of a method of manufacturing a germanium-based membrane, in accordance with one or more embodiments;

FIG. 3 is a graph showing deposition temperature as a function of time, in accordance with one or more embodiments;

FIG. 4 is a schematic view of an example computing device of a controller used to execute the steps of the method of FIG. 2, in accordance with one or more embodiments;

FIG. 5A is an image of a typical uniform PGe layer on a 100 mm wafer, in accordance with one or more embodiments;

FIG. 5B is a graph showing XRR measurements of the PGe layer of FIG. 5A, before and after annealing at 300° C., with the critical angles of both PGe layer (θ_{PGe}) and Ge substrate (_{θ}Ge) in dotted lines, in accordance with one or more embodiments;

FIG. 5C is a SEM micrograph showing a cross-sectional view of PGe layer before (PGe) annealing, in accordance with one or more embodiments;

FIG. 5D is a SEM micrograph showing a cross-sectional view of PGe layer after (APGe) annealing at 300° C.;

FIG. 5E is a SEM micrograph showing a top view of PGe layer before annealing, in accordance with one or more embodiments;

FIG. 5F is a SEM micrograph showing a top view of PGe layer after annealing at 300° C., in accordance with one or more embodiments;

FIGS. 6A and 6B are AFM scans showing a top view of a PGe layer before annealing, in accordance with one or more embodiments;

FIGS. 6C and 6D are AFM scans showing a top view of a PGe layer after annealing at 300° C., showing no significant topological surface changes, in accordance with one or more embodiments;

FIGS. 7A through 7D are SEM micrographs showing cross-sectional views of Ge layers at 5 nm, 30 nm, 60 nm, and 100 nm of deposited nominal thickness, respectively, in accordance with one or more embodiments;

FIGS. 7E through 7H are SEM micrographs showing top views of the Ge layers of FIGS. 7A-7D, respectively, in accordance with one or more embodiments;

FIGS. 8A through 8I are SEM micrographs showing the evolution of a Ge layer deposited on a PGe substrate with an increasing thickness of deposited material corresponding to 0 nm, 5 nm, 10 nm, 30 nm, 50 nm, 60 nm, 80 nm, 100 nm, and 250 nm, respectively, in accordance with one or more embodiments;

FIGS. 9A through 9F are 5×5 μm² AFM scans showing top surface views of Ge layers of thicknesses of 60 nm, 100 nm, 250 nm, 500 nm, 750 nm, and 1000 nm, respectively, in accordance with one or more embodiments;

FIG. 9G is a graph of surface RMS roughness as a function of the nominal thickness of the Ge layer during the deposition process of FIGS. 9A-9F, with the vertical dashed line indicating the complete coalescence of the layer and the horizontal dashed line corresponding to the initial surface roughness of the PGe layer, in accordance with one or more embodiments;

FIG. 9H is a graph showing surface pit diameter and pit depth as a function of the nominal thickness of the Ge layer during the deposition process of FIGS. 9A-9F, in accordance with one or more embodiments;

FIG. 9I is a graph showing pit density as a function of the nominal thickness of the Ge layer during the deposition process of FIGS. 9A-9F, in accordance with one or more embodiments;

FIG. 10 is a schematic view showing an initial PGe substrate, 3D island deposition, coalescence of islands into Ge membrane, and thickening of the Ge membrane by 2D layer-by-layer deposition, in accordance with one or more embodiments;

FIG. 11A is an image of a ˜1 μm thick Ge membrane deposited on top of a 1 μm thick PGe layer with high porosity, in accordance with one or more embodiments;

FIG. 11B is an AFM scan of the surface of the Ge membrane of FIG. 11A, in accordance with one or more embodiments;

FIG. 12A is a graph of a 2θ out-of-plane XRD scan of the Ge membrane deposited on 54% and 70% PGe substrates and of the Ge bulk substrate as a reference, with logarithmic scale on y-axis, in accordance with one or more embodiments;

FIG. 12B includes in-Plane pole figures of the Ge membranes deposited on PGe substrates with 54% and 70% porosity, in accordance with one or more embodiments;

FIG. 13A is a SEM micrograph showing a cross-sectional view of the Ge membrane on the weak porous interface illustrating the fracture of the nanostructured interface and the uncoupling of the membrane, with an inset showing a zoom on the unreconstructed high porosity layer underneath the membrane, in accordance with one or more embodiments;

FIG. 13B is an image of a 100 mm Ge membrane transferred to flexible substrate using adhesive tape, in accordance with one or more embodiments;

FIG. 13C is an optical microscope image of the PGe remnants on the substrate after the uncoupling, in accordance with one or more embodiments;

FIG. 13D is an optical image of the Ge substrate after cleaning, in accordance with one or more embodiments;

FIG. 13E is an AFM scan of the Ge substrate after cleaning, in accordance with one or more embodiments;

FIG. 14A is a SEM micrograph showing a cross-sectional view of an example PGe substrate, in accordance with one or more embodiments;

FIG. 14B is a 5×5 μm² AFM scan of the surface of the PGe substrate of FIG. 14A, in accordance with one or more embodiments;

FIG. 14C is an ellipsometry mapping of the PGe substrate of FIG. 14A showing thickness and porosity uniformity, in accordance with one or more embodiments;

FIG. 15A is a 5×5 μm² AFM scan of an example Ge membrane deposited on the PGe substrate of FIG. 14A, showing a surface roughness below 1 nm, in accordance with one or more embodiments;

FIG. 15B is an in-plane pole figure of the Ge membrane of FIG. 15A around the Ge (220) axis, with the dashed circle and arrow represent a 6° off-cut orientation of the Ge membrane compared to a normal axis, in accordance with one or more embodiments;

FIG. 16A is an image of a Ge substrate after membrane uncoupling, showing PGe remnants, in accordance with one or more embodiments;

FIG. 16B is an optical microscope image of the PGe remnants of FIG. 16A, in accordance with one or more embodiments;

FIG. 16C is a SEM micrograph of the PGe remnants of FIG. 16B, in accordance with one or more embodiments;

FIG. 16D is an image of a Ge substrate of FIG. 16A after cleaning of the PGe remnants, in accordance with one or more embodiments;

FIG. 16E is an optical microscope image of the cleaned PGe substrate of FIG. 16D, in accordance with one or more embodiments;

FIG. 16F is a SEM micrograph of the cleaned PGe substrate of FIG. 16E, in accordance with one or more embodiments;

FIG. 17A is a schematic view of a method of cleaning a Ge substrate of its PGe remnants, in accordance with one or more embodiments;

FIG. 17B is a 5×5 μm2 AFM scan of the recovered Ge substrate of FIG. 17A after chemical cleaning with RMS roughness of 0.8 nm, in accordance with one or more embodiments;

FIG. 18A is an image of a PGe layer of the recovered Ge substrate of FIG. 17A, in accordance with one or more embodiments;

FIGS. 18B and 18C are ellipsometry mapping of the recovered Ge substrate of FIG. 17A showing the uniformity, in thickness and porosity, respectively, in accordance with one or more embodiments;

FIG. 19A is a graph showing membrane coupling strength as a function of porosity, in accordance with one or more embodiments; and

FIG. 19B is a graph showing RMS roughness as a function of porosity, in accordance with one or more embodiments.

### DETAILED DESCRIPTION

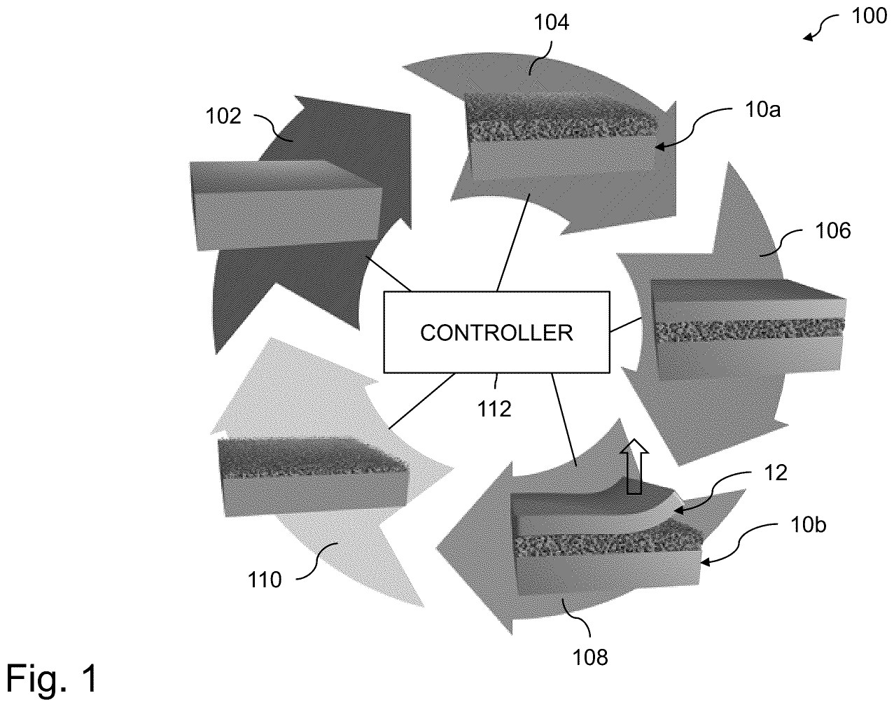

FIG. 1 shows an example of a system 100 for manufacturing a germanium-based membrane, in accordance with an embodiment. As depicted, the system 100 has a substrate holding device 102, a porosification device 104, a membrane formation device 106, an uncoupling device 108 and a cleaning device 110. The system 100 can be used in cycles in which uses a germanium substrate as an input and provides a first output of a germanium-based membrane, and a second output of a germanium substrate (of smaller thickness than the original germanium substrate) which can be used as an input in a further manufacturing cycle. The system 100 has a controller 112 which is generally communicatively coupled to the devices 102-110 directly or indirectly, and which can control the manufacturing of germanium-based membranes in one or more subsequent cycles, depending on the embodiment.

More specifically, the holding device 102 is used to hold the germanium substrate which is used as an input of the system 100. The holding device 102 may move the germanium substrate along a manufacturing line and across the porosification device 104, the membrane formation device 106, the uncoupling device 108 and the cleaning device 110, depending on the embodiment. The holding device 102 can include a robotized arm, for instance.

Turning now to the porosification device 104, this is where the germanium substrate is etched to form a porous layer of germanium within a top layer of the germanium substrate. The porosification device 104 can be configured to expose the top layer of the germanium substrate to a chemically active etchant which can form pores through a thickness of the germanium substrate. The initial porosity of the porous layer depends on the porosification device 104 and porosification parameters, for instance. As shown, the porous layer of the germanium substrate defines pore walls made integral to the germanium substrate and perhaps extending relatively perpendicularly therefrom. The germanium substrate having the porous layer can be referred to as first germanium substrate 10a herein.

The membrane formation device 106 is generally provided in the form of a deposition chamber which may or may not be under vacuum during the formation of the membrane 12. The membrane formation device 106 is configured for depositing, growing or otherwise forming a non-porous layer of germanium-based material on the porous layer of the first germanium substrate 12a. In some embodiments, the germanium-based material can be monocrystalline germanium, polycrystalline germanium, amorphous germanium and the like. In certain embodiments, the germanium-based material can be a germanium-based alloy including at least one group IV element such as silicon (Si), tin (Sn), lead (Pb), and/or carbon (GeC). Additionally or alternatively, the germanium of the substrate, and/or the germanium of the non-porous layer can be doped germanium (e.g., p-doped, n-doped).

As discussed in further detail below, the formation of the non-porous layer of germanium-based material is performed at a first temperature below a reorganization temperature of the porous layer of the first germanium substrate 10a. In some embodiments, more specifically those in which the deposition chamber is under vacuum, the first temperature ranges between 25° C. and 325° C., preferably between 100° C. and 325° C., and most preferably between 200° C. and 325° C. For instance, the reorganization temperature can range between 325° C. and 450° C., depending on the deposition conditions. In embodiments where the germanium-based material is monocrystalline germanium, the first temperature can range between 275° C. and 325° C. In embodiments where the germanium-based material is amorphous germanium, the first temperature can range between 25° C. and 100° C. The reorganization temperature of the porous layer of the first germanium substrate 10a can change depending on the embodiment. For instance, the reorganization temperature of the porous layer can be about 400° C. under hydrogen atmosphere. However, in most standard deposition conditions, the reorganization temperature of the porous layer is well below 400-450° C. In some other examples, the reorganization temperature can vary depending whether the atmosphere includes vacuum, hydrogen, nitrogen, argon, and the like. As shown, the morphology of the porous layer remains unchanged between the porosification step and the membrane deposition step. In other words, the pore walls of the porous layer after the membrane formation have a morphology which is similar to an initial morphology of the pore walls of the porous layer prior to the membrane formation.

The uncoupling device 108 is configured for exerting an uncoupling force onto the germanium-based membrane. The uncoupling force can be a pulling force or a shearing force, depending on the embodiment. The uncoupling force will tend to move the germanium-based membrane 12 away from the first germanium substrate 10a, thereby breaking the pore walls of the porous layer of the first germanium substrate 10a and freeing the germanium-base membrane 12 from the first germanium substrate 10a and obtaining a second germanium substrate 10b.

As depicted, the uncoupling of the germanium-based membrane 10b leaves the second germanium substrate 10b with porous germanium remnants made integral to the germanium substrate and protruding therefrom. The porous germanium remnants can generally include germanium crystallites having a dimension ranging between 1 nm and 19 nm. Thanks to the small size of these germanium crystallites, the porous germanium remnants can be easily cleaned using techniques which will be further described below. It was found that by keeping the first temperature below the reorganization temperature, the initial morphology of the pore walls does not change, which can leave porous germanium remnants which are more easily removable than if the germanium-based membrane had been formed at higher temperatures. The cleaning device 110 can be used to remove the porous germanium remnants from the germanium substrate, thereby providing yet another input for the system 100. An example of such a cleaning device is described below.

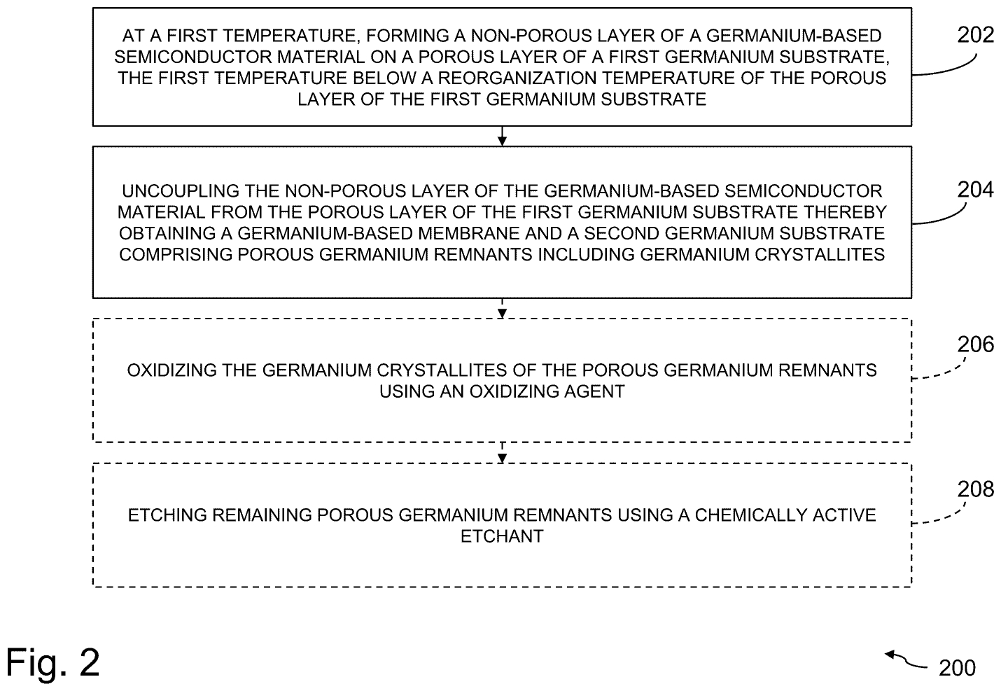

FIG. 2 shows a flow chart of a method 200 of manufacturing a germanium-based membrane, in accordance with an embodiment. The method 200 can be performed using the system 100 described with reference to FIG. 1, for instance.

As depicted, the method 200 has a step 202 in which a non-porous layer of a germanium-based material is formed on a porous layer of a first germanium substrate at a first temperature. The first temperature is below a reorganization temperature of the porous layer of the germanium substrate. Accordingly, the morphology of the porous layer does not substantially change throughout the formation of the non-porous layer. In some embodiments, the formation of the non-porous layer is performed within a vacuum environment. In these conditions, it was found preferably to keep the first temperature between 25° C. and 325° C., preferably between 100° C. and 325° C., and most preferably between 200° C. and 325° C. which can correspond to the reorganization temperature of the porous layer of the first germanium substrate. It is understood that the reorganization temperature of the porous layer of the first germanium substrate may change depending on the conditions under which the non-porous layer of the germanium-based material is formed.

At step 204, the non-porous layer of the germanium-based material is uncoupled from the porous layer of the first germanium substrate thereby obtaining a germanium-based membrane and a second germanium substrate comprising porous germanium remnants including germanium crystallites. In some embodiments, the step 204 of uncoupling can involve the use of an uncoupling force which can be a pulling force pulling the germanium membrane away from the first germanium substrate, a shearing force directed along a plane extending between the germanium membrane and the first germanium substrate, to name a few examples.

As discussed above, the uncoupling of the germanium-based membrane leaves porous germanium remnants on respective surfaces of the first and second germanium substrates. These porous germanium remnants can include germanium crystallites having a dimension ranging between 1 nm and 19 nm. In certain embodiments, the first germanium substrate and the second germanium substrate can include porous germanium remnants having a porosity ranging between 40 and 80%. The smallness of such remaining crystallites can facilitate the cleaning process, an example of which is described in the following sentences. The cleaning process can include one or more techniques to remove the porous germanium remnants from the first germanium substrate and/or the second germanium substrate. For instance, at step 206, an oxidizing agent such as hydrogen peroxide (H₂O₂), nitric acid (HNO₃), or ozone (O₃) is used to oxidize the germanium crystallites of the porous germanium remnants of the first and/or second germanium substrate(s). This first oxidizing step 206 can remove the coarse portions of the germanium crystallites of the porous germanium remnants. As such, the finer portions of the germanium crystallites, such as a base portion of the porous layer, can be removed using a chemically active such as hydrofluoric acid (HF), hydrochloric acid (HCl), hydrobromic acid (HBr) and the like at step 208. It was found that this two-part cleaning process can reach a satisfactory surface roughness level while being more chemically gentle on the remaining germanium substrate, which can reduce material losses in at least some circumstances. For instance, this removal technique can leave the first and/or second germanium substrate(s) with a surface roughness below 1 nm. It is intended that other porous germanium remnants removing techniques can be used in some other embodiments. In some embodiments, the oxidizing agent oxidizes and slowly etches the PGe remnants. The etching agent can mainly dissolve the oxide formed during the previous step (can include rest of PGe remnants) to obtain smooth oxide-free surface. In some other embodiments, Alternatively, very diluted etching solutions of Ge (e.g., usually mixtures of oxidizing and etching agent) can be used under the conditions that low etching rate is maintained (few tens of nm/min, for instance). Subsequent dissolution of remaining oxides may also necessary in these latter embodiments.

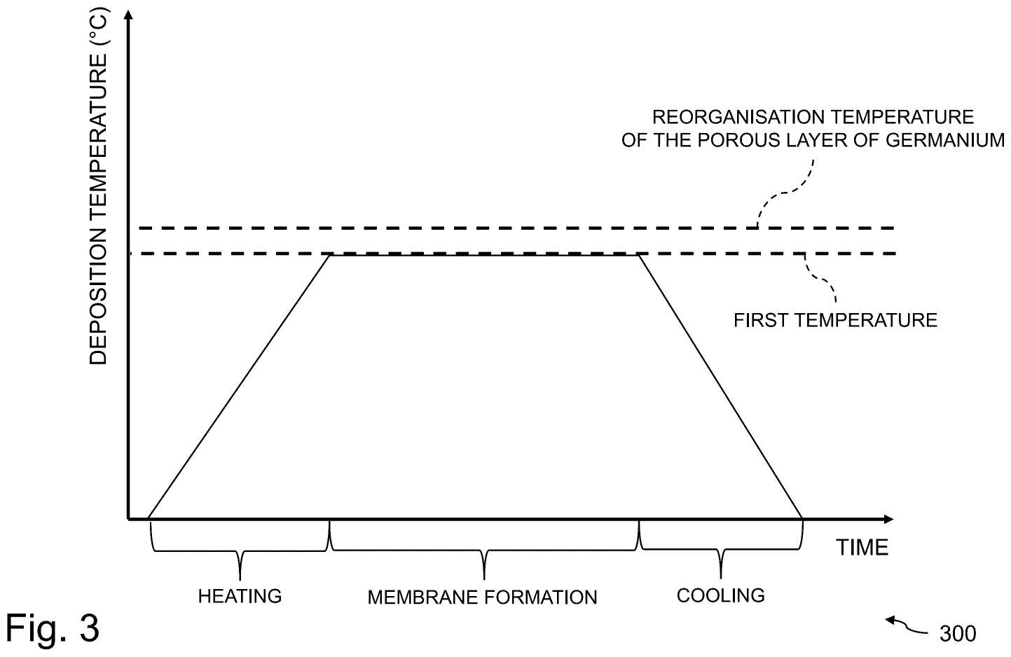

FIG. 3 shows a graph 300 of an exemplary temperature curve used for the deposition of the non-porous layer of germanium-based material. As shown, the temperature within the vacuum chamber (or within any other deposition environment), ramps up for a first period of time until the first temperature is reached. That plateau is maintained at least for a second period of time, during which the non-porous layer of germanium-based material is formed onto the porous layer of the germanium substrate. After the non-porous layer of suitable thickness has been formed, the temperature cools down for a third period of time. As depicted, the temperature reaches the first temperature but never exceeds the reorganization temperature of the porous layer of the germanium substrate. As briefly discussed above, by performing the deposition below the reorganisation temperature, then the pore walls of the porous layer of the germanium substrate can maintain their morphology through the deposition. In other words, the pore walls never reorganize to form bigger crystallites such as pillars and the like, which are more cumbersome to clean off the remaining germanium substrate.

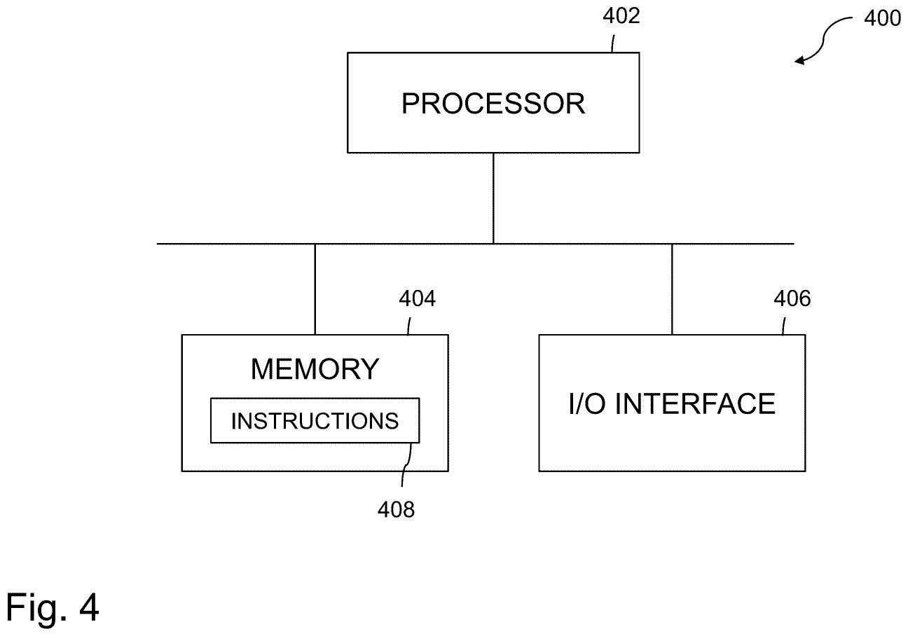

Referring now to FIG. 4, the computer of the system of FIG. 1 can be provided as a combination of hardware and software components. The hardware components can be implemented in the form of a computing device 400, an example of which is described with reference to FIG. 4. The computing device 400 can have a processor 402, a memory 404, and I/O interface 406. Instructions 408 for manufacturing the germanium membrane can be stored on the memory 404 and accessible by the processor 402.

The processor 402 can be, for example, a general-purpose microprocessor or microcomputer, a digital signal processing (DSP) processor, an integrated circuit, a field-programmable gate array (FPGA), a reconfigurable processor, a programmable read-only memory (PROM), a programmable logic computer (PLC), or any combination thereof.

The memory 404 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like.

Each I/O interface 406 enables the computing device 400 to interconnect with one or more input devices, such as a keyboard(s), mouse(s), or accessible database(s), or with one or more output devices such as monitor(s), external network(s), or accessible database(s).

Each I/O interface 406 enables the computer to communicate with other components, to exchange data with other components, to access and connect to network resources, to serve applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fibre optics, satellite, mobile, wireless (e.g., Wi-Fi, WiMAX), SS7 signaling network, fixed line, local area network, wide area network, and others, including any combination of these.

The computing device 400 and any software application that can be run by the computing device 400 are meant to be examples only. Other suitable embodiments of the computer can also be provided, as it will be apparent to the skilled reader.

### Example 1—Wafer-Scale Ge Freestanding Membranes for Lightweight and Flexible Optoelectronics

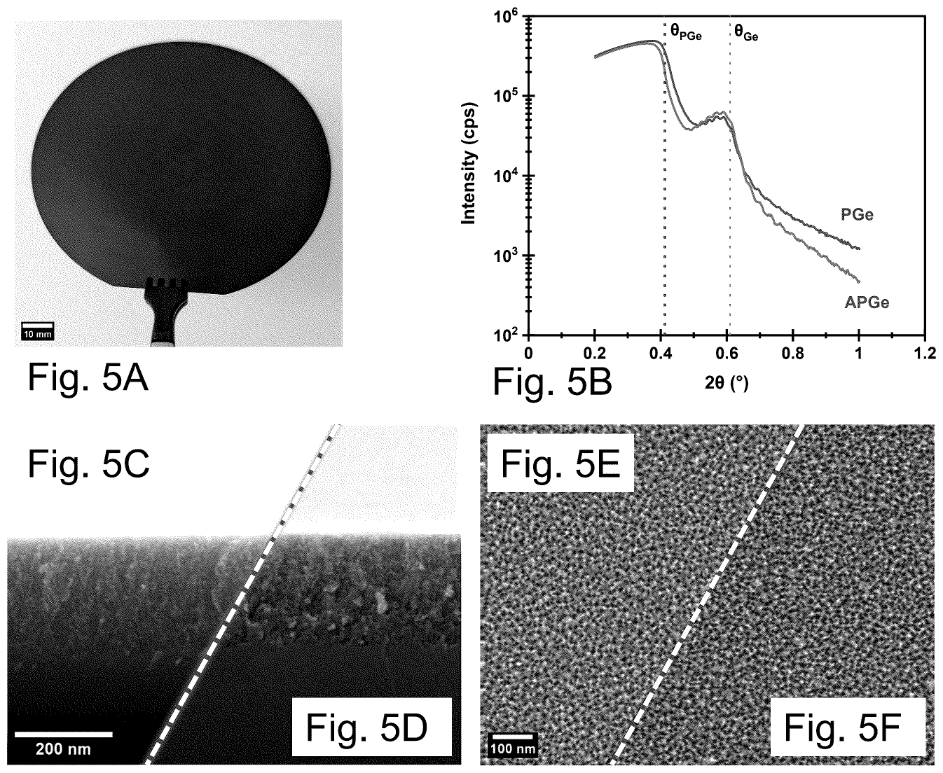

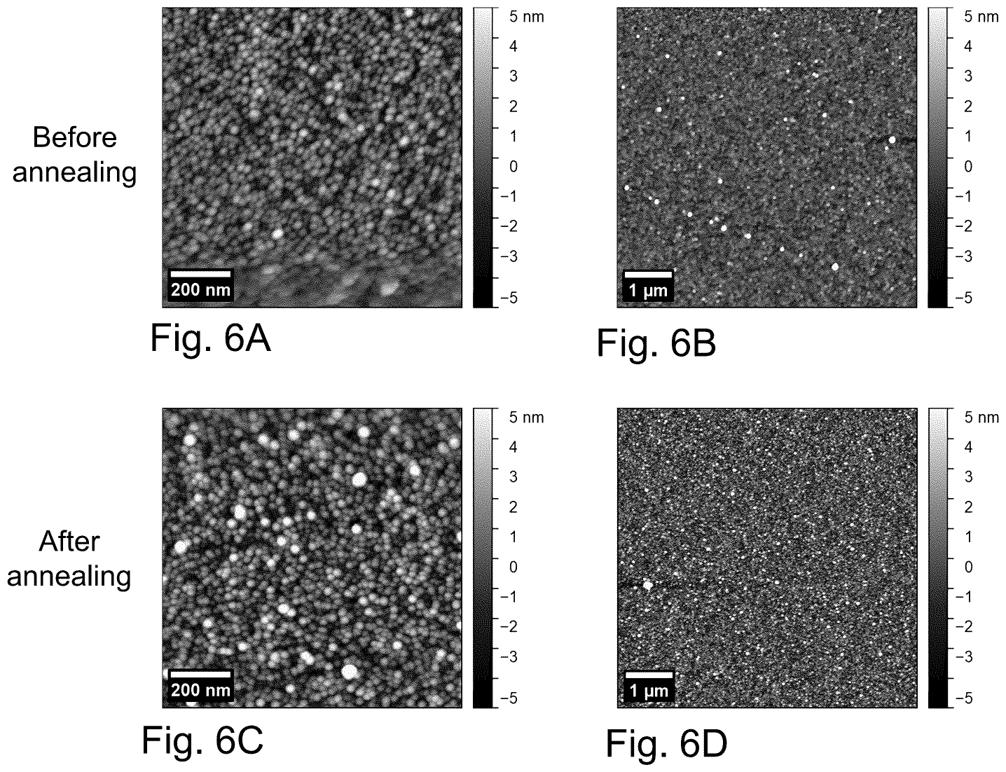

The PGe substrates, used for material deposition, are prepared by bipolar electrochemical etching (BEE) on P-type Ge substrate, in HF-based electrolyte. The process enables fine tuning of the PGe thickness and porosity, providing on-demand properties while ensuring a low surface roughness and a substrate oriented crystalline nature, making them a viable option for deposition of layers. The produced PGe thickness and porosity demonstrate an overall variation standing below 2% across the wafer. FIG. 5A depicts an optical image of typical 100 mm Ge substrate, with homogeneous porous layer on top, produced by BEE. To shed light on the initial stages of the Ge epitaxy on PGe nanostructures, 230 nm thick uniform PGe layers (FIG. 5C) were first considered over 100 mm Ge wafer with intermediate porosity around 54%, calculated from critical angle measured by X-ray reflectivity (FIG. 5B), and having a surface RMS (Root mean square) roughness below 2 nm (FIG. 6). All the investigated samples have been grown at 300° C. in Chemical beam epitaxy reactor (CBE) equipped with solid source Ge. The deposition rate has been maintained constant throughout this study at 0.5 μm/h. Additionally, since an objective is to perform material deposition of Ge on PGe structure, the deposition temperature needs to be sufficiently low to avoid PGe reorganization as discussed further below.

To evaluate the stability of the porous structure at the deposition temperature, the PGe substrate has been first in-situ annealed at 300° C. for 30 min and characterized by XRR, scanning electron microscopy (SEM) and atomic force microscopy (AFM). FIG. 5B shows XRR measurement of the porous Ge layer before and after annealing, with a negligible shift of the PGe layer critical angle (θ_{PGe}), from 0.414° to 0.410° (less than 1% increase of porosity), signifying that the porosity remains unchanged. Furthermore, FIGS. 5C-F depict cross-sectional and top-view SEM images, showing identical in-plane and in-depth porous morphologies before and after the annealing step. The surface RMS roughness does not undergo any major changes either, with only a slight increase from 1.1 nm to 1.6 nm. (FIG. 6). Accordingly, Ge deposition can be performed on PGe substrate while preserving the porous structure integrity. For deposition temperatures of 350° C. and above, morphological transformation of the PGe has been found to occur, making it unsuitable for the present example.

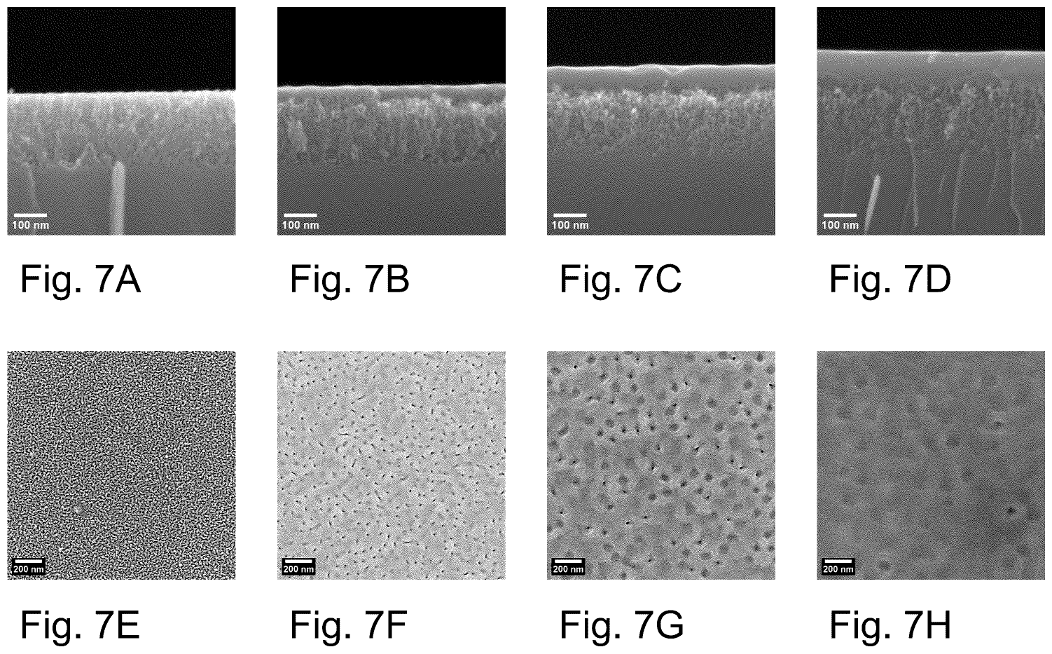

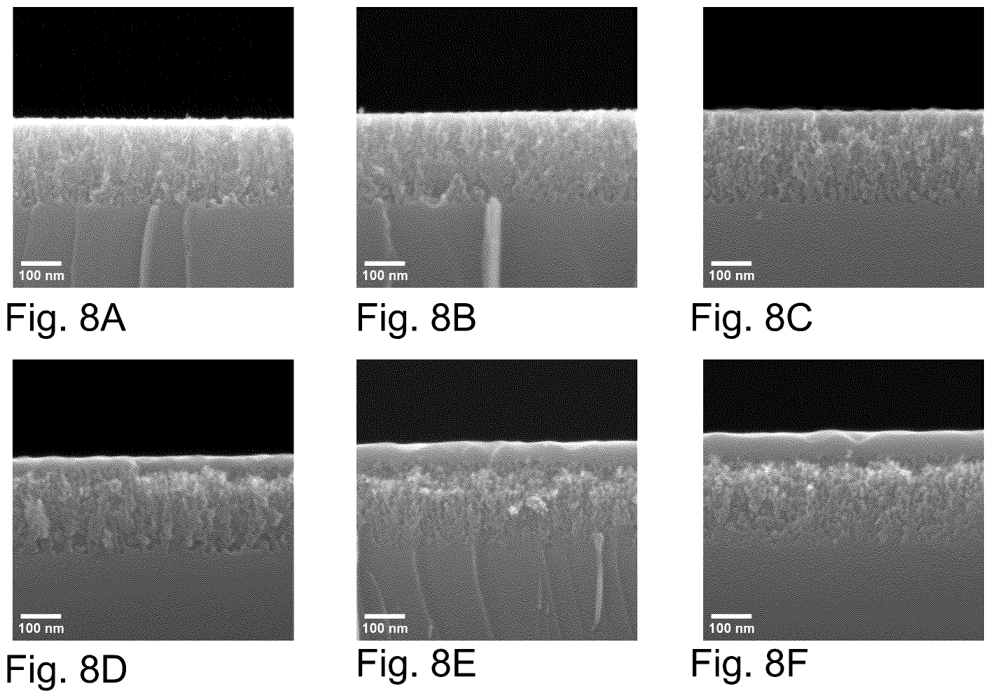

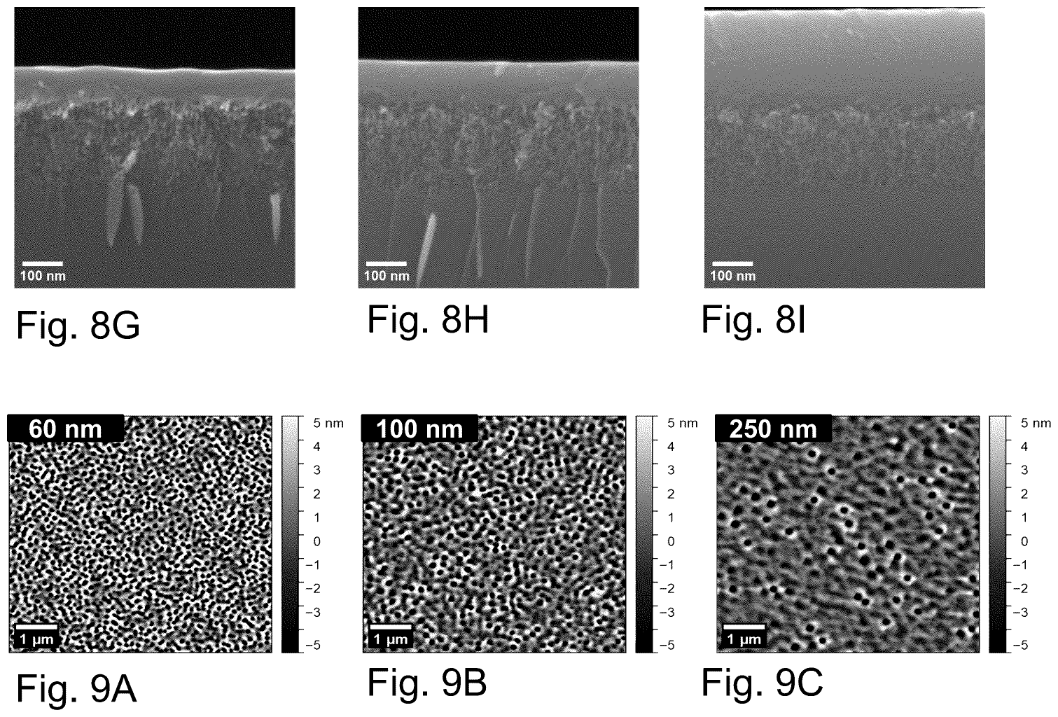

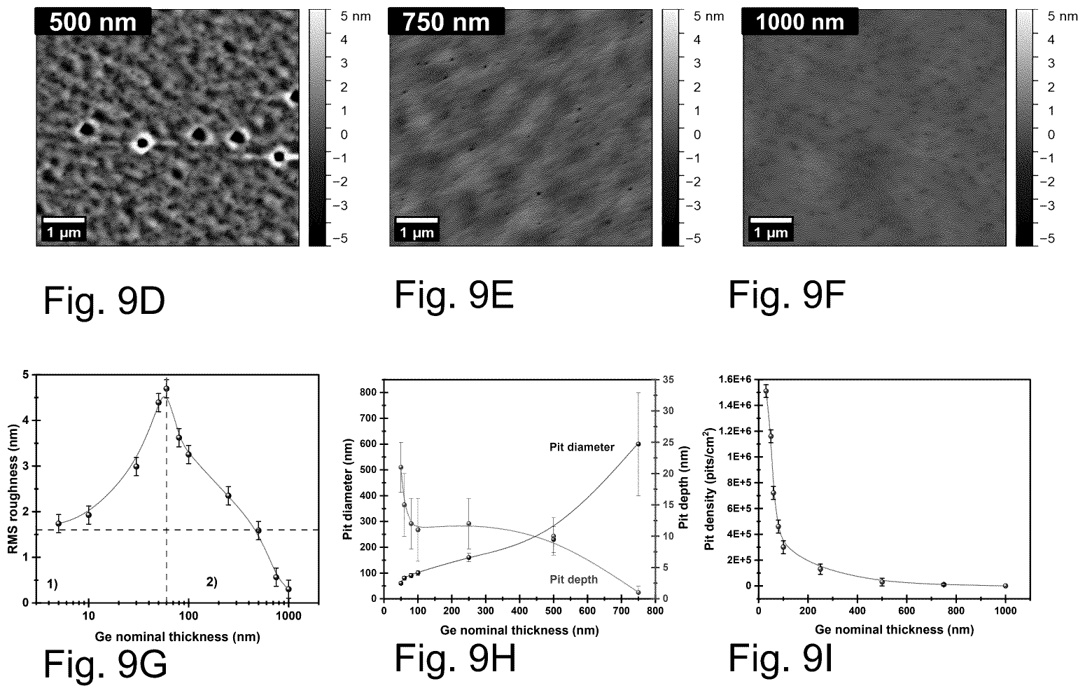

To study the initial deposition stages and understand the Ge nucleation on PGe substrates, several samples have been prepared with deposited Ge nominal thicknesses ranging from 5 nm to 1 μm. The morphological evolution of the epilayers was systematically evaluated as a function of the nominal thickness of Ge on the PGe structure and characterized via SEM and AFM. Typical cross-sectional and top-view SEM images taken from samples with 5, 30, 60 and 100 nm deposited Ge thickness are shown by FIGS. 7A-D and FIGS. 7E-H respectively. Additional data are provided in FIG. 8. The results reveal that the nucleation occurs on the top surface of the pore walls, forming nanoscale three-dimensional (3D) islands (FIGS. 7A and 7E). The combined low substrate temperature and small pores' size (below 10 nm) is likely to limit the adatoms diffusion into the porous structure in favor of top surface nucleation. As more material is added, the 3D island's size increase, eventually coalescing to form a 2D Ge membrane (FIGS. 7B and 7F). Although, the densely packed nucleation enables continuous Ge membrane formation, the corresponding surface morphology remains rough as can be seen in FIGS. 7C and 7G. The observed behavior is also confirmed by AFM morphological investigations (FIG. 9). Indeed, the analysis of the RMS roughness indicates that the roughness rises first, with increasing Ge thickness up to 60 nm and then drops rapidly towards surfaces with sub nanometer roughness for membranes thicknesses beyond 750 nm.

Additionally, during the Ge nucleation on PGe structure, the first islanding regime starting with 3D nucleation, considerably impacts the surface morphology through islands size increase and consequent seed islands coalescence, leading to the observed RMS roughness increase. The coalescence of the nanosized islands occurs for deposited Ge thicknesses higher than 10 nm giving rise to the appearance of pits. The islanding phase has been reported in case of low temperature deposition of Ge on porous Si substrate. However, in the latter case, the lattice mismatched strain and the differences in the thermal expansion coefficients have been shown to induce grain boundary formations that prohibits the full islands coalescence into homogeneously dense epilayer. Moreover, similar behavior has already been reported at micrometer scale, where persistent separated microcrystals occur for Ge deposition on Si micropillars, while good quality suspended Ge layer can be achieved by high temperature epitaxy/annealing on Ge micropillars. Furthermore, the formation of good quality dense epilayer has also been recently reported by GaN nucleation on porous GaN buffer on sapphire substrate, suggesting that the homoepitaxial deposition is a key for obtention of fully coalesced layers on porous substrates at low temperature.

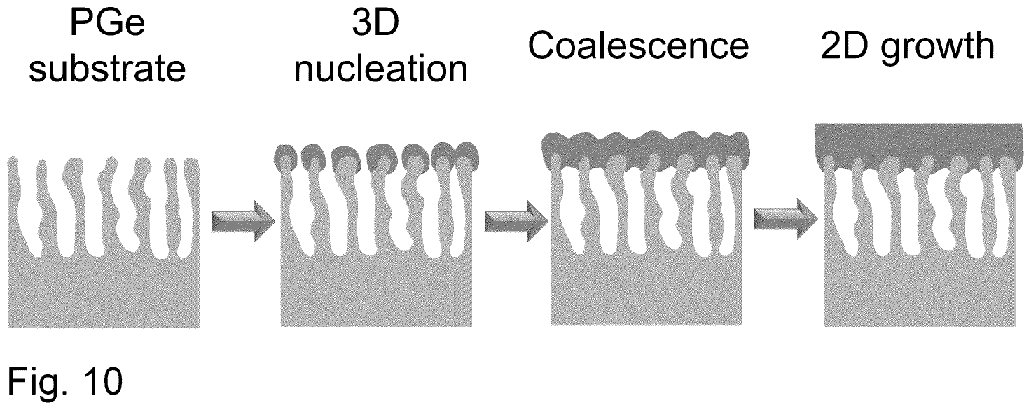

While the islands coalescence starts in an early nucleation stage, promoting initial pit formation, some deep pits crossing the membrane are still present up to a deposited Ge thickness of 50 nm (FIG. 8E). The depth of these pits is referred to as “pit depth” herein. Also considering the measured RMS roughness peak around 60 nm of deposited Ge (FIG. 9G), this specific thickness appears as a critical one for the membrane formation process by homoepitaxial nucleation on PGe structure. Accordingly, the critical thickness (Tc) is defined as the minimum thickness required to ensure the full islands' coalescence into continuously dense membrane, without deep pits crossing the entire membrane. Once Tc is reached, the fully densified membrane can be further thickened, while improving the surface morphology as shown in FIGS. 9G-I. The pits start merging (FIGS. 9A-F) and their depth gets continuously reduced as more Ge material is deposited (FIG. 9H), while the surface pit density decreases until the obtention of perfectly flat surface seen in FIG. 9I. As the thickness rises beyond Tc, the deposition becomes basically dominated by 2D layer by layer mode. Consequently, the RMS roughness decreases exponentially testifying an improved membrane's surface morphology. After the deposition of a 750 nm thick Ge layer, significant drop in the submicron scale pits' depth and increase of their diameter occur leading to their merging and flattening towards a smooth surface. Consequently, the large pits turn into surface ripples-like morphology making them strongly anisotropic and hardly quantifiable (FIGS. 9E-H). Despite the persistence of nanoscale sized pits remnants (FIG. 9E), the surface roughness is already well below 1 nm, testifying an excellent morphology suitable for further deposition. Indeed, as shown by the FIG. 9D, imperfection free completely smooth surface with RMS roughness of 0.3 nm is obtained for a 1 μm thick membrane. The critical thickness for fully coalesced layer may vary depending on the PGe layer's properties, as the high porosity structures obviously requires more material to ensure the transition from 3D nucleation to 2D deposition mode. These results demonstrate that once the deposited thickness exceeds Tc, and the membrane is fully densified, its surface morphology improves with more deposited material. All corresponding deposition stages on porous substrates are schematically illustrated in FIG. 10.

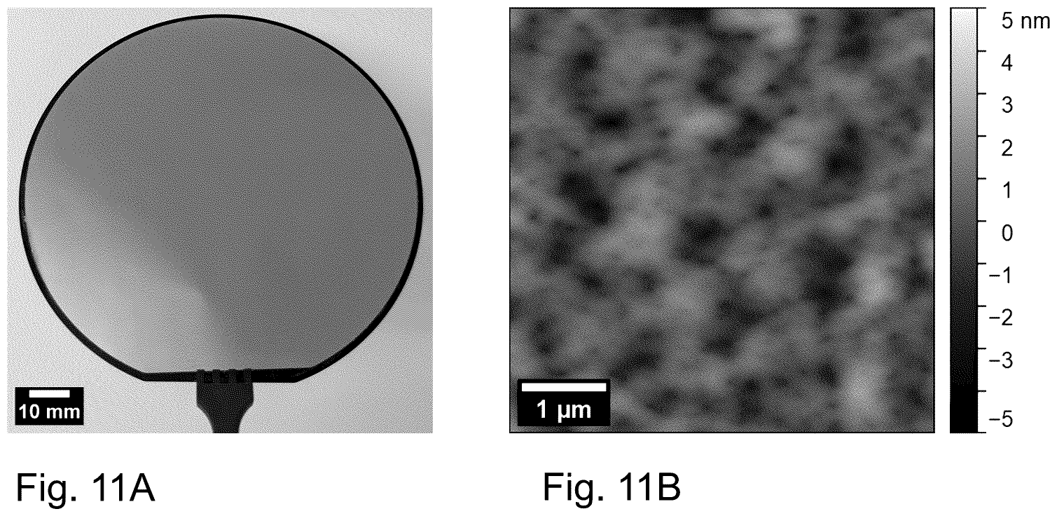

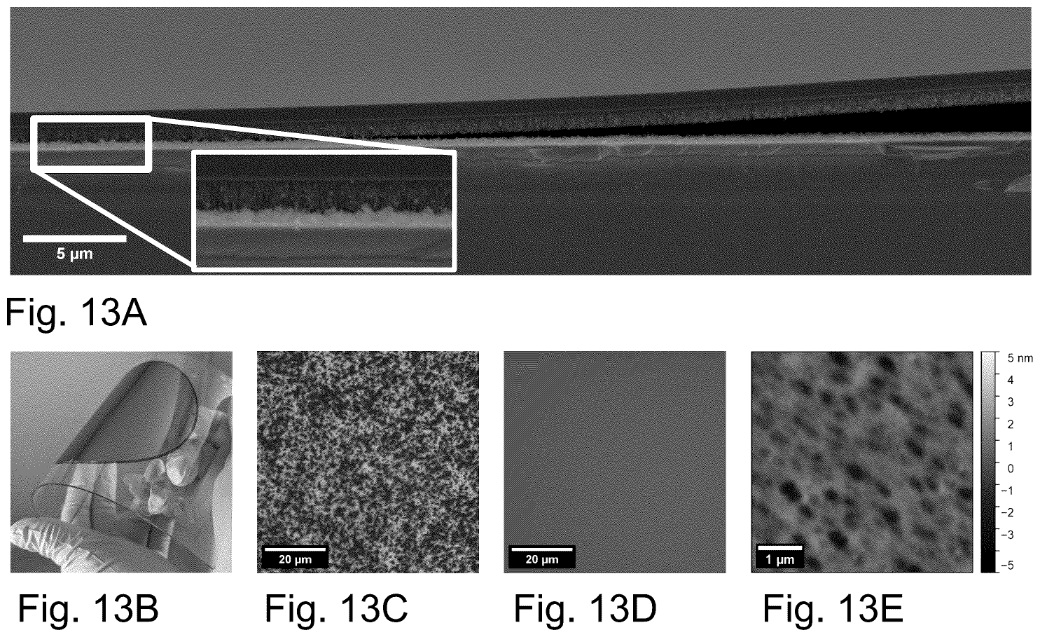

To assess the feasibility of the proposed FSM deposition process for different PGe thicknesses and porosities, 1 μm thick Ge membrane has been grown under the same conditions on 1 μm thick PGe layer with approximately 70% porosity. This represents an extreme case of thick and high porosity PGe substrate. Interestingly, fully densified Ge FSM has been successively fabricated at 100 mm wafer-scale (FIG. 11A), while the high porosity layer remains unreconstructed (as shown later in the inset of the FIG. 13A). The FSM show RMS roughness of 1.2 nm, as illustrated by the AFM scan in FIG. 11B. Indeed, the surface still shows ripple-like morphology. Referring to the AFM analysis of the FSM thickness evolution for 54% porosity, such a surface state is likely to characterize fully coalesced pits with depth variation below 5 nm. This surface condition makes the layers comparable to membranes grown on 54% PGe substrate with thickness between 500 and 750 nm. It is understood that higher porosity generates sparser nucleation sites and eventually necessitate more material to form a fully coalesced layer and annihilate all the pits on the surface. The surface morphology can be further improved by thickening of the membrane following the expected flattening trend.

PGe layers were prepared by optimized BEE process of Ga-doped, 100 mm (100) Ge wafers with 6° off-axis miscut towards (111) orientation and 8-30 mΩ·cm in resistivity, provided by Umicore. The BEE was performed in a custom made 100 mm porosification cell, using SP-50 BioLogic generator. Prior to this process, Ge wafers were treated with HF (49%) solution for 5 min to dissolve any native oxides present on the surface, rinsed with EtOH (99%) and dried under N₂ flow. Samples were then introduced into the porosification cell with HF (49%):EtOH (99%) (4:1, V:V) electrolyte and etching and passivation pulses with 1 s duration and 1 s rest time at the end of each cycle were applied. The medium porosity (˜54%) layers were formed using 1 mA·cm⁻² symmetric etching/passivation current density. To produce high porosity layers (˜70%), the etching current density was increased to 2 mA·cm⁻². At the end of BEE process substrates with PGe structure were rinsed with EtOH (99%), dried under N₂ flow and introduced into the loading chamber of the CBE reactor.

Ge deposition was carried-out in VG Semicon VG90H CBE reactor, with a load-lock, transfer module maintained at ˜6.10-9 Torr, and thermocouple as a means of monitoring the temperature during the deposition. The solid source of Ge, with a K-Cell temperature at 1250° C., was used to deposit Ge with nominal deposition rate of 500 nm·h-1. Samples were introduced to the deposition chamber directly at 300° C. Then various nominal thickness of Ge (5-1000 nm) was deposited on PGe substrates at 300° cat chamber pressure ˜6.10-6 Torr.

After the uncoupling of the membrane with adhesive tape, the retrieved substrate was immersed in concentrated H2O2 (30%) solution for 1 min to fully oxidize the remains of the PGe structure. This is followed by deoxidation in concentrated HF (49%) prior to the reporosification.

The top-view and cross-section of PGe layers and Ge/PGe structures were observed with a Zeiss LEO 1540 XB scanning electron microscope at 4.3 mm of working distance and 20 keV of acceleration voltage, to evaluate the thickness of deposited material and any morphological changes of the structure. The surface morphology of the membranes was evaluated using Veeco Dimension 3100, atomic force microscopy system, in tapping mode with SSS-NCHR silicon probe and scan resolution 512×512 pixel. The collected AFM profile data on various wafers locations were also used to evaluate the pits' size and depth evolution on the FSM's surface for various thicknesses. The structural properties of PGe and epitaxial layers were investigated using Rigaku smartlab HRXRD system with Cu Kα X-ray source, Ge (220)×2 monochromator on the incident beam, and HYPIX-3000 hybrid pixel array 2D detector. The XRR was used to determine the critical angle of PGe layers, which is directly linked to the porosity. The out-of-plane and in-plane XRD configurations were used to identify crystalline quality of the Ge membranes.

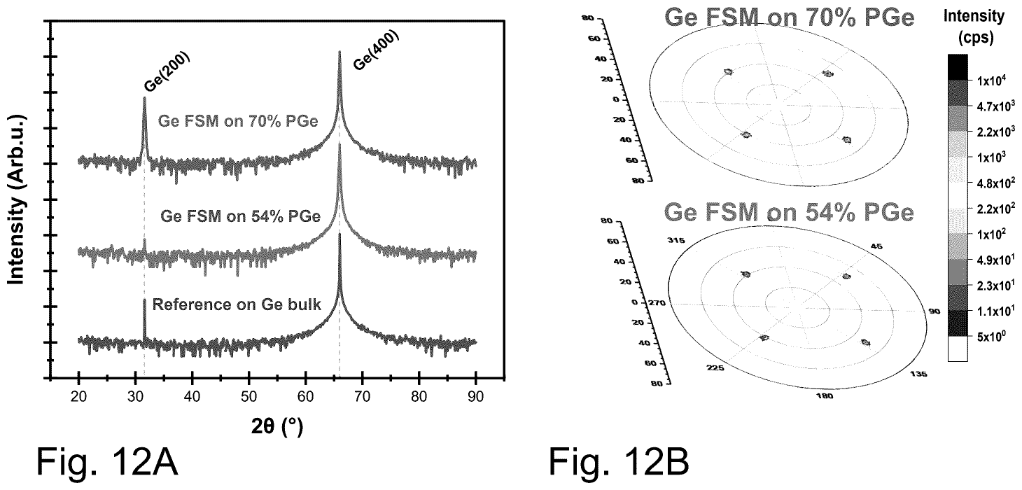

To evaluate the crystalline the quality of the membranes grown either on 70% or 54% PGe substrates, a comprehensive X-ray diffraction (XRD) analysis was conducted. The out-of-plane 2θ scans in FIG. 12A reveal unique well-defined Ge (400) and (200) peaks that correspond to the (001) substrate orientation indicating the monocrystalline nature of the FSM grown on both 54% and 70% PGe substrates. This is possible due to the substrate-oriented crystallites of the PGe layer, which transfer their orientation to the membrane during material deposition. Furthermore, the in-plane configuration was used to ensure a low penetration depth of the beam, probing only the Ge membrane, thus discriminating its signal from that of the substrate. Interestingly, both in-plane pole figures of Ge (220), shown by the FIG. 12B, depict 4 well defined sharp peaks, with fourfold symmetry, corresponding to the cubic crystal structure of Ge, undoubtedly confirming the single-crystal quality of the Ge FSMs independently of the PGe's porosity used as the substrate.

The presence of unreconstructed PGe structure underneath the Ge SFM constitutes a well-adapted separation layer with nanostructured interface allowing for membrane lift-off. Indeed, the cross-sectional SEM image (FIG. 13A) shows the easy fracture of the 70% porous interface between the Ge membrane and the bulk substrate. For demonstration purpose, a successful full 100 mm wafer Ge FSM release was achieved by simple adhesive polymer tape and transfer to a transparent, flexible plastic holder (FIG. 13B).

Furthermore, the unreconstructed PGe separation layer also offers a unique opportunity for substrate reuse, as the bulk substrate material remains largely intact, with only PGe's residuals on the top surface as shown by the FIG. 13C. Compared to sub-micron to micron scale pillars formed by high-temperature annealing methods, in this case, the PGe crystallites are only few nm in size and have high specific surface compared to the volume of the Ge material (in respect to Ge bulk material or large pillars). This allows to completely oxidize the majority of the PGe structure in H₂O₂ solution, and then dissolve it in HF with minimal bulk Ge material etching, compared to wet etching methods. This treatment results in a clean surface with RMS roughness ˜0.72 nm (FIGS. 13D-E), which is suitable for additional cycles of porosification/material deposition/membrane uncoupling, as previously demonstrated. This further highlights the advantages of using unreconstructed porous interface. The estimated Ge consumption is approximately 1 μm per cycle, since the bulk material stays intact during the substrate cleaning. This process advantageously produces multiple Ge membranes from a single substrate with minimal material loss. Accordingly, a 175 μm thick Ge wafer could be reused around 30 times before reaching the thickness of 145 μm (Thinnest commercially available 100 mm Ge wafers) and being recycled. Giving the rarity and cost of Ge, this method significantly reduces the cost of Ge-based devices, while offering all the advantages of FSM.

In summary, this example demonstrated the deposition of monocrystalline Ge membranes at 300° C. on PGe substrates, while leaving the porous structure of the substrate unchanged during the deposition. The initial nucleation stages on porous structure have been experimentally investigated showing two deposition regimes. Initially the deposition is dominated by 3D nucleation on top of the pores and their coalescence. Once the Ge membrane reaches the critical thickness of coalescence, a dense membrane is formed, and the deposition becomes governed by 2D layer-by-layer deposition regime. At this stage, the remaining pits at the surface are being annihilated during the thickening of the membrane and good surface quality, with an RMS roughness below 1 nm, can be reached. The XRD analysis demonstrate the monocrystalline quality of the grown Ge membranes for all samples independently of their porosity and thickness. The results show that PGe layers can be used to fabricate uncoupleable wafer-scale Ge FSM. Moreover, the nanometric crystallite size and high specific surface of the PGe remnants on the substrate surface, allow an easy cleaning process by oxidation and reuse of the substrate for production of multiple Ge FSM. Furthermore, these findings also pave the way to the fabrication of wafer scale FSM from low temperature grown small bandgap materials for mid-IR optoelectronics such as Ge(Si)Sn.

### Example 2—Sustainable Production of Ultrathin Ge Freestanding Membranes

In this example, an optimized wafers-scale process is described. This process enables the Ge FSM fabrication using a porosification lift-off technique, involving the PGe structures with reduced thickness and porosity, allowing for both reduced Ge consumption and improved Ge FSM surface quality. A successful cleaning of the entire 100 mm substrate after the uncoupling of the Ge FSM was demonstrated using slow chemical etching of the PGe remnants. The reporosification of the recovered substrate is achieved, resulting in a new high-quality uniform PGe suitable for the further production of Ge FSM from the same substrate. These results highlight the potential of using Ge FSM to reduce the rare materials consumption during optoelectronic device production, offering a sustainable pathway for the next-generation high-performance devices.

PGe layers were formed using an optimized bipolar electrochemical etching (BEE) process on top of Ge substrates. The p-type gallium (Ga) doped, 100 mm Ge wafers oriented along the (100) axis, with 6° off-axis miscut towards (111) orientation and resistivity of 8-30 mΩ·cm were used in this study. Before the PGe formation, the Ge substrate was deoxidized in concentrated hydrofluoric acid (HF, wt %) solution for 5 min, followed by rinsing in anhydrous ethanol (EtOH, 99 wt %) and drying under nitrogen (N₂) flow. The BEE was carried out in a custom-build 100 mm porosification cell, consisting of a polytetrafluoroethylene (PTFE) body, copper (Cu) backside electrode, and platinum (Pt) wire working electrode, filled with 300 ml of electrolyte solution composed of HF (49 wt %):EtOH (99 wt %) in 4:1 (V:V) proportions. The SP-50 BioLogic generator was used to apply cyclic square 1 s pluses of etching and passivation with 1.5 and 1.0 mA·cm⁻² current density, respectively. Each cycle was separated by 1 s rest time and 420 cycles were applied in total to produce the PGe layer. At the end of the process, PGe substrates were rinsed with EtOH (99 wt %), dried under N₂ flow, and subsequently placed into the loading chamber of the deposition chamber under vacuum.

The ˜1 μm thick Ge membrane was grown in VG Semicon VG90H CBE reactor at 300° C., using a solid source of Ge heated at 1250° C. with a nominal deposition rate of 500 nm·h-1 as described previously.

After the material deposition, the Ge FSM is uncoupled using adhesive tape and transferred on a flexible Polyvinyl Chloride (PVC) substrate. The recovered Ge substrate has been reconditioned by immersion in concentrated hydrogen peroxide (H₂O₂, 30 wt %) solution for 1 min, at room temperature, to transform the remaining PGe crystallites at the surface in germanium dioxide (GeO₂) and etch them slowly away. The substrate has been subsequently deoxidized in concentrated HF (49 wt %) to dissolve the remaining Ge oxides on the surface and recover a flat surface. The reconditioned substrate is then reporosified, using the same BEE conditions as would have been used on a conventional germanium substrate.

The PGe thickness, porosity, and their uniformity over the 100 mm wafer were characterized using a J.A. Woollam Co. VASE instrument in the spectral range between 500 and 900 nm. The measuring points were radially paced every 30° with an in-between point spacing of 5 mm along the radius of the wafer. The PGe thickness was also verified using SEM imaging of the PGe layer cross-section, also revealing the morphology of the nanostructure. The presence/lack of the PGe layer remnants on the substrate after the uncoupling and cleaning process was observed using optical microscopy (confocal microscope Keyence VK-X1100 with 150× lens) and SEM imaging of the substrate's plan view. All the SEM observations were performed at a 4.0 mm working distance with Thermo Fisher Scios 2 SEM using 20 keV acceleration voltage for the electron beam.

The Park system NX20, atomic force microscope (AFM) was used to evaluate the surface topology of the PGe layer, Ge FSM membrane, and of the recovered substrate after cleaning. The AFM scans were performed in tapping mode using a super sharp silicon probe (SSS-NCHR) and a scan resolution of 512×512 pixels over a 5×5 μm² area. The scan data were then processed using Gwyddion software to obtain the Root mean square (RMS) roughness values.

The investigation of the structural properties of Ge FSM was conducted using Rigaku Smartlab high-resolution X-ray diffraction (XRD) system in the in-plane configuration equipped with Cu Kα X-ray source (wavelength λ(Cu Kα)=1.5406 Å), Ge (220)×2 monochromator on the incident beam, and two-dimensional hybrid pixel array semiconductor X-ray detector (HYPIX-3000). The in-plane pole figure XRD measurements were employed to assess the crystalline quality of the Ge membranes while restricting the depth of beam penetration.

The fabrication process of Ge FSM through the porosification lift-off technique consists of four main steps. First, a high-porosity (60-80%) porous germanium (PGe) layer is formed at the Ge substrate surface by electrochemical etching in HF:EtOH electrolytic solution. This is followed by low-temperature deposition of the Ge membrane on top of the PGe layer. The membrane is then mechanically uncoupled from the substrate, which is facilitated by the fragile nanostructured PGe interface between the Ge bulk substrate and the Ge FSM. After uncoupling, the PGe remnants at the surface of the recovered parent Ge substrate are oxidized using an H₂O₂ solution followed by their complete dissolution in HF and reuse of the parent Ge substrate for reporosification and repeating the process of Ge FSM fabrication.

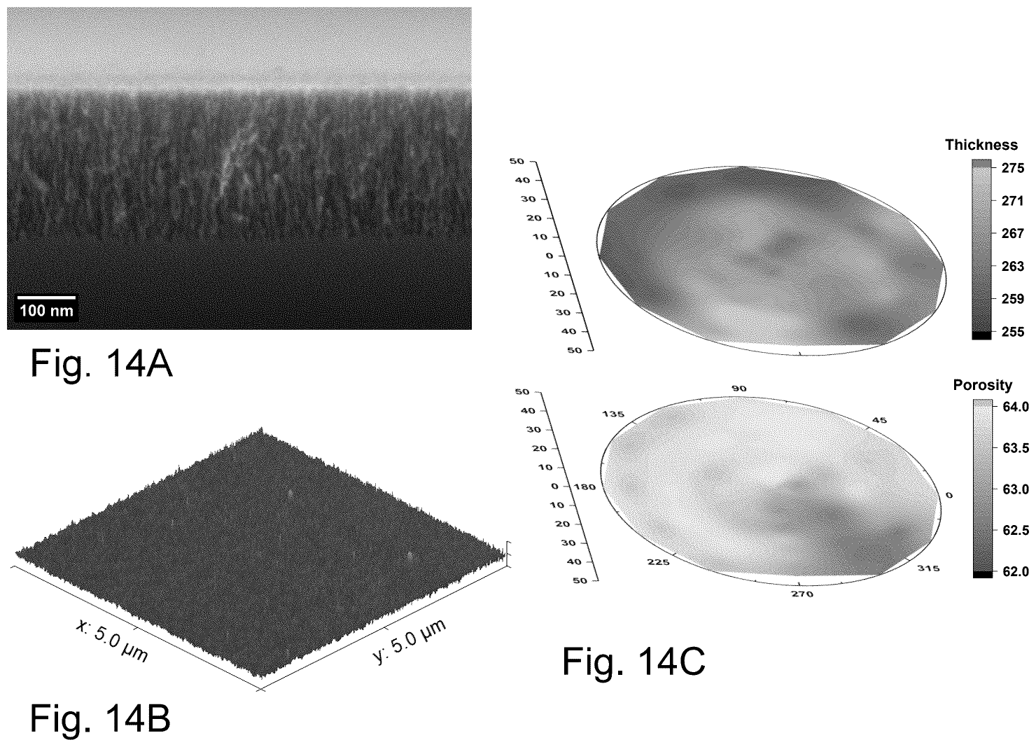

The Ge FSM fabrication cycle begins with the formation of a high-quality PGe layer on top of the Ge substrate. Any major defects or inhomogeneities in the PGe structure can be further transferred to the Ge membrane, impacting its quality. FIG. 14A shows SEM cross-sectional micrograph of the PGe layer used in this example. The typical sponge-like porous structure shows a well-defined interface between the PGe layer and bulk material, with ˜264 nm thickness and 63% porosity. Furthermore, the ellipsometry mapping of the 100 mm wafer, shown in FIGS. 14B and 14C, demonstrates the overall uniformity of the porous nanostructure in both the thickness and porosity with respective variations of ±4 nm and ±1% across the entire surface of the wafer. Moreover, the porous structure manifests a surface roughness below 2 nm, as illustrated by FIG. 14C. The closely packed crystallites of the high-porosity PGe layers (60-80%) make an excellent template for the deposition of Ge membrane structures while enabling an easy uncoupling without additional steps.

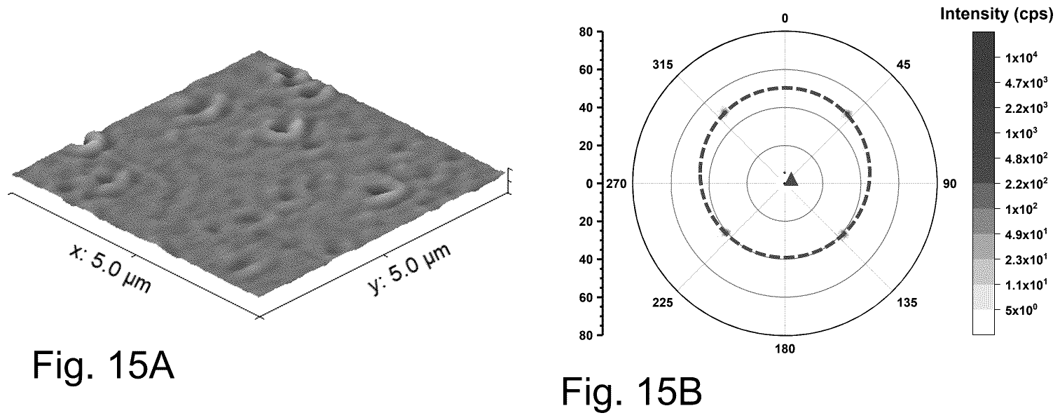

A 1 μm thick Ge membrane is then grown, at 300° C., on top of the PGe structure, resulting in a smooth surface with RMS roughness around 0.7 nm, as demonstrated by FIG. 15A. A few shallow pits and undulations are still identifiable on the surface but can be annihilated by increasing the membrane's thickness. Depending on the targeted application the thickness of the membrane can be varied from ˜100 nm to few μm. However, for membranes thinner than 1 μm the surface roughness can increase up to 5 nm for the thinnest membranes. This way, the amount of Ge material used for device integration can be directly controlled to use only the quantity of Ge necessary for its function and hence limit the waste of material.

The crystalline quality of the membrane is verified using X-ray diffraction in in-plane configuration, to limit the beam penetration. The resulting in-plane pole figure around the Ge (220) axis displays 4 sharp peaks with 90° rotational symmetry around their central axis as depicted by FIG. 15B. This pattern corresponds to the diamond cubic crystal structure of Ge, confirming the high crystalline quality of the Ge membrane. Interestingly, the central axis of the sample demonstrates a 6° shift from the measurement axis, as illustrated in FIG. 15B. This shift is attributed to the parent substrate's 6° miscut from [100] orientation towards the [111] axis. Since the porous structure maintains the original substrate orientation, it can transfer even this characteristic to the Ge membrane, resulting in a monocrystalline epilayer with the same 6° off-cut as the parent substrate.

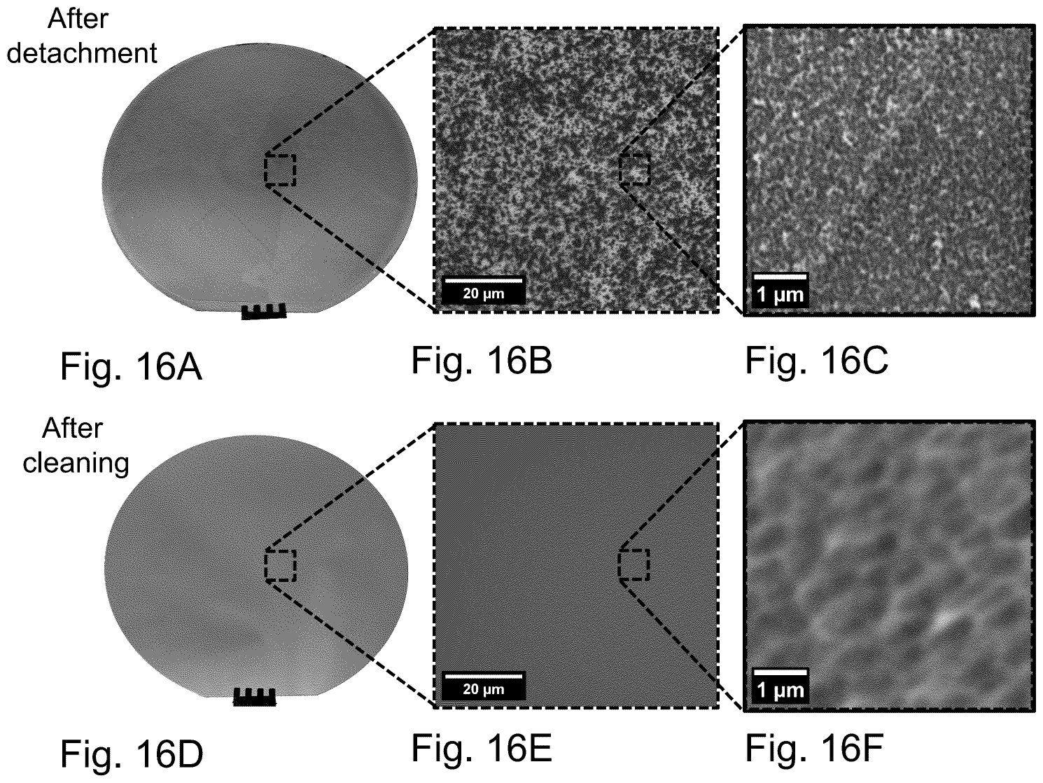

Once the Ge membrane is formed, the high-porosity nanostructure underneath represents a perfect fragile interface allowing easy uncoupling and transfer to the substrate. Using an adhesive polymer tape, the Ge FSM can be separated from the parent substrate and transferred to a flexible PVC holder. After the uncoupling, irregular remnants of the porous structure are still present on the surface of both the substrate and membrane as illustrated by FIGS. 16A-C. To eliminate these porous remnants, a simple chemical cleaning process is employed. The chemical etching of Ge in aqueous solutions functions on the principles of the formation and dissolution of the GeO₂, where H₂O₂ acts as an oxidizing agent which transforms the Ge surface in GeO₂. At the same time, the reduction of the H₂O₂ at the surface of Ge provides the holes necessary for the dissolution of the oxide. When the substrate is immersed in concentrated H₂O₂, the solution transforms the remaining PGe structure's high specific surface area in GeO₂ and starts slowly etching it away. This chemical etching of Ge can be described by Equation (1) and (2), where Equation (1) represents the formation of the GeO₂ on the Ge surface, and Equation (2) its dissolution into H2GeO₂ a tetravalent form stable in aqueous solution with pH<8.5:

$$Ge + 2 {H}_{2} {O}_{2} \to {GeO}_{2} + 2 {H}_{2} O , \qquad ( 1 )$$

$${GeO}_{2} + {H}_{2} O \to {H}_{2} {GeO}_{3} . \qquad ( 2 )$$

Compared to techniques involving high-temperature annealing and PGe reconstruction in crystallites with size superior to 100 nm, the high porosity nanostructure with significantly higher specific surface area and only 5-10 nm thick pore walls, allows for isotropic etching by H₂O₂ at a very slow rate (few nm/min). This avoids the substantial chemical etching of the substrate (few μm) necessary for the planarization of larger features while maintaining control over the etching process due to the slow etching rate. The remaining oxides on the substrate's surface are then dissolved in HF solution during the deoxidation step prior to the reporosification. This results in a remnant-free surface as shown in FIGS. 16D-F.

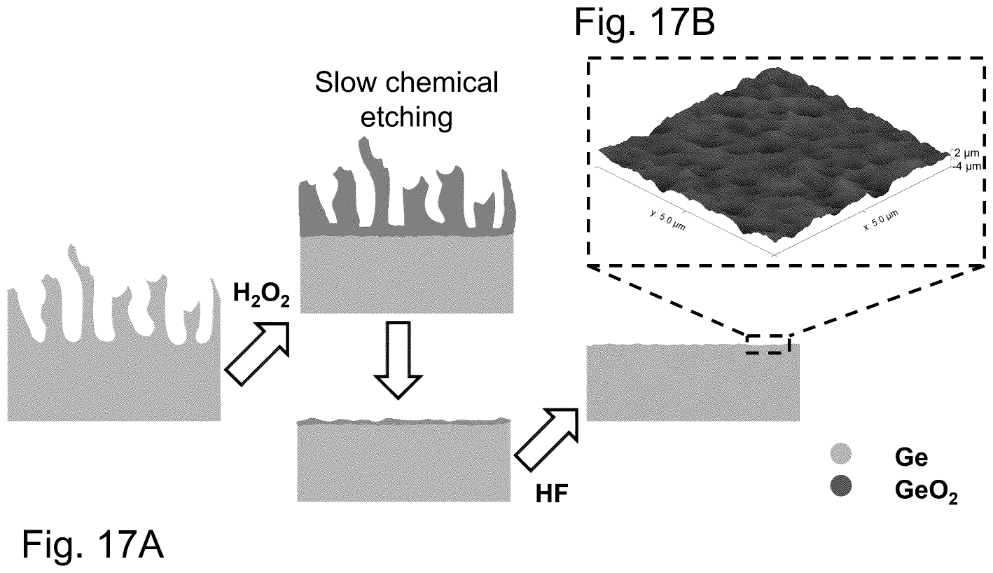

The entire chemical cleaning process is schematically illustrated in FIG. 17A. The AFM scan of the recovered substrate in FIG. 17B shows a flat surface with surface roughness below 1 nm. The apparent waving of the cleaned surface represents a slight variation in the initial Ge bulk/PGe interface formed during the BEE process, as the bottoms of the pores are not all perfectly aligned. This effect is then partially mitigated directly by the first anodic step of the BEE process during the formation of the new PGe layer.

The PGe remnants on the Ge FSM backside have the same nature as they are formed by the separation of the uniform PGe layer. This means that the same approach can also be used for membrane cleaning. In the case of applications where the Ge membrane does not play an active role in the final function and serves mainly as the crystalline substrate for the deposition of epitaxial structures, membrane cleaning shouldn't be necessary.

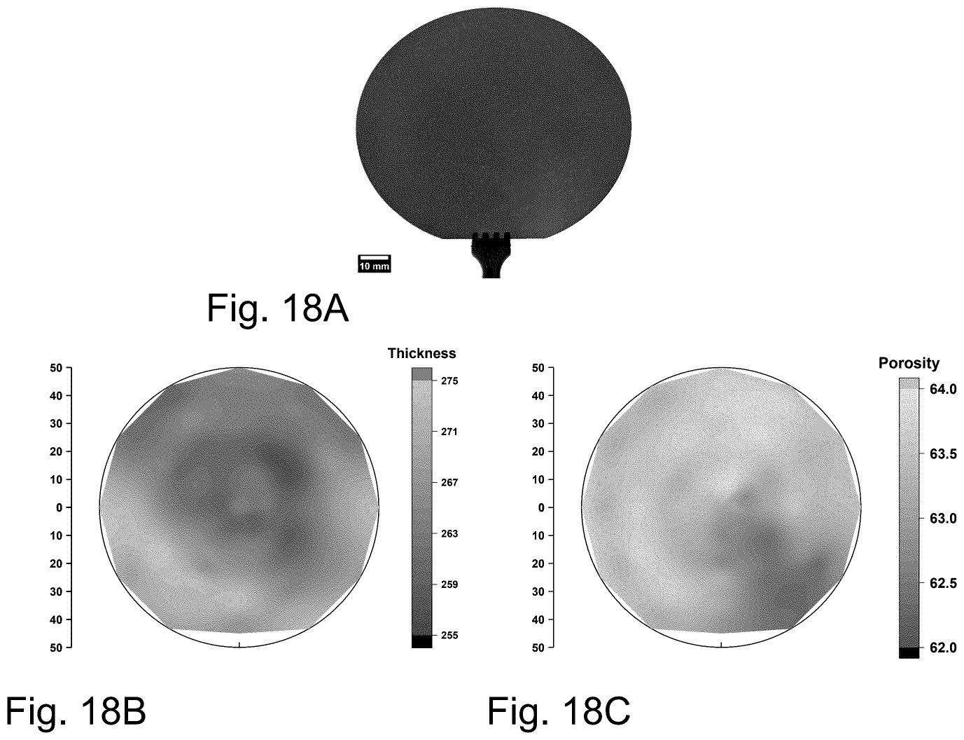

To complete the cycle, the recovered parent substrate then undergoes a second porosification process to obtain a new PGe layer, presented in FIG. 18A. The BEE conditions are identical to the ones previously used on the conventional germanium substrate. It presents the same thickness and porosity with high uniformity across the entire 100 mm wafer as demonstrated by ellipsometry mapping present in FIGS. 18B-C. The new PGe layer presents a thickness of 265±5 nm and porosity of 63±1%, both these values are the same as on the conventional germanium substrate, demonstrating that the small surface undulations on the recovered substrate don't influence the BEE process. This new high-quality PGe structure then allows for new deposition of the Ge membrane and fabrication of multiple Ge FSM from the same substrate, by repeating the process. This demonstrates that the Ge FSM can be fabricated with a consumption of less than 300 nm of the original Ge substrate while allowing for easy substrate reuse without the involvement of expensive reconditioning techniques such as chemical mechanical polishing. The use of an optimized PGe layer enables improvements in both Ge FSM surface quality and material consumption of the substrate per cycle. The lower porosity allows for more closely packed nucleation sites, resulting in a reduction of the membrane's surface roughness to 0.7 nm from 1.2 nm on 70% porosity PGe substrate. Additionally, the reduced PGe thickness, further lowers the substrate consumption by over 70%, while maintaining the ease of uncoupleability of the Ge FMS.

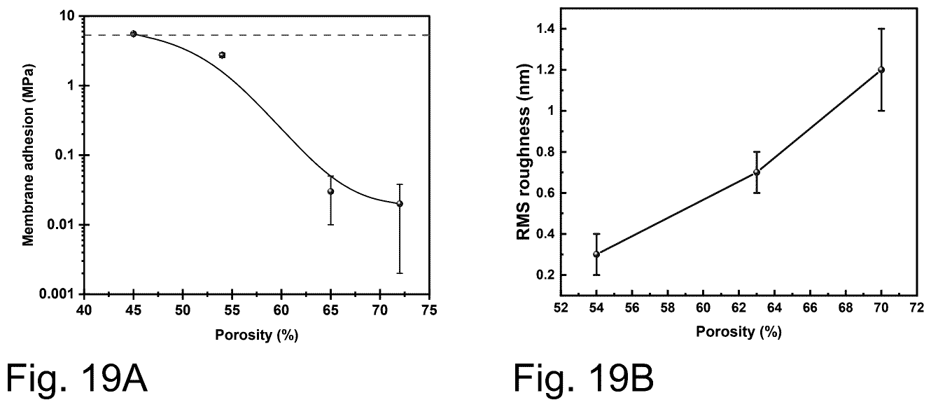

FIG. 19A shows the evolution of the membrane's coupling strength to the substrate as a function of the PGe layer porosity. It demonstrates that the coupling strength of the membrane to the substrate increases with decreasing porosity of the PGe layer, as the denser PGe layers provide stronger links between the substrate and the membrane. PGe layers with porosity above 50% provide weak coupling strength, while PGe layers with porosity below 50% offer strong coupling strength. The dashed line represents the measurement limit of the setup used for the evaluation of the coupling strength. FIG. 19B shows the evolution of the membrane's RMS roughness as a function of the PGe layer porosity. As depicted, the RMS roughness increases with the initial porosity of the PGe layer. For instance, in some embodiments, the initial porosity of the porous layer of the germanium substrate can be selected based on an expected surface roughness. In certain embodiments, the porous germanium remnants leave the germanium substrate with a surface roughness below 1 nm when the porous layer has an initial porosity ranging between 50 and 70%. In some other embodiments, the porous germanium remnants leave the germanium substrate with a surface roughness below 0.5 nm when the porous layer has an initial porosity ranging between 50 and 59%.

In numbers, around 300 nm of the original substrate is consumed per produced membrane. This value includes the thickness of the PGe layer (˜270 nm) and the front/back etching of the substrate during the cleaning process (˜30 nm). By considering a conventional 100 mm Ge wafer with a thickness of 175 μm and its thinnest commercially available counterpart with a thickness of 140 μm, around 35 μm of the substrate can be used for Ge FSM production before losing its structural integrity. This results in over 100 membranes produced from a single 100 mm wafer. The number of reuses can be further increased by the use of thicker substrates, which bring additional benefits such as a reduction in material lost during the sawing process of Ge wafers from a solid ingot grown by the Czochralski method. Alternatively, the Ge substrate can be bonded on a holder (e.g., Si substrate) for mechanical support, allowing for the use of almost the entire substrate's thickness and enabling over 500 reuses. This number is expected to further grow with scaling on larger substrates, as larger diameter wafers are considerably thicker.

In comparison, techniques involving high-temperature annealing present large pillars with diameter superior to 100 nm, cannot be reconditioned without etching of substantial material's quantity (few μm) or involvement of costly chemical mechanical polishing (CMP). Considering single-sided chemical etching of 5 μm per reuse, this approach presents more limited number of Ge FSM fabricated from a single wafer. However, this approach holds its advantage for applications involving high processing temperatures (>400° C.) as the high specific area PGe structure cannot be maintained under these conditions.

2D-assisted epitaxy, in theory, could eventually offer infinite reuse of the substrate. However, it is still in relatively early research stages, especially in case of group IV materials such as Ge, using new approach on local nucleation and lateral overdeposition on the 2D interface. Moreover, other challenges such as large surface deposition and transfer of high-quality interfaces need to be resolved for its viable application.

Considering, the rarity of the Ge, the complexity of its recovery from end-of-life optoelectronic devices, and the recent geopolitical situation around this material, the Ge FSM represent a sustainable alternative to conventional Ge substrates. It offers to significantly reduce the quantity of Ge material integrated into optoelectronic devices while allowing for cost reduction thanks to the limited Ge use and substrate recycling.

As can be understood, the examples described above and illustrated are intended to be exemplary only. For instance, it is understood that the substrate holding device, the porosification device and the cleaning device can be omitted in some embodiments. Although some of the examples presented herein are directed to germanium-based semiconductor materials, it is intended that the disclosed method and system can be applied to any other suitable semiconductor material including, but not limited to, silicon (Si), indium tin oxide (ITO), zinc oxide (ZnO), III-V semiconductor materials such as gallium arsenide (GaAs), indium phosphide (InP), gallium nitride (GaN), Indium gallium arsenide (InGaAs), indium gallium phosphide (GaInP), aluminum gallium arsenide (AlGaAsP), indium gallium arsenide phosphide (InGaAsP), aluminum gallium indium phosphide (AlGaInP), aluminum gallium indium phosphide (InAlGaP), aluminum gallium indium phosphide (InGaAlP), aluminum gallium indium phosphide (AlInGaP), III-V heterostructures such as gallium nitride on silicon (GaN/Si), aluminum nitride on silicon (AlN/Si), gallium arsenide on silicon (GaAs/Si), gallium phosphide on silicon (GaP/Si), indium gallium arsenide on silicon (InGaAs/Si), aluminum indium nitride on silicon (AlInN/Si), gallium indium nitride on silicon (GaInN/Si), or any other III-V or III-N semiconductor materials. It is understood that the reorganization temperature may vary from one semiconductor material to another. For instance, the reorganization temperature of porous silicon ranges between about 475° C. and 525° C.; the reorganization temperature of porous GaN ranges between about 875° C. and 925° C.; the reorganization temperature of porous InP ranges between about 425° C. and 475° C.; and the reorganization temperature of porous GaAs ranges between about 475° C. and 525° C. The scope is indicated by the appended claims.

What is claimed is:

1. A method of manufacturing a germanium-based membrane, the method comprising:
at a first temperature, forming a non-porous layer of a germanium-based material on a porous layer of a first germanium substrate, the first temperature below a reorganization temperature of the porous layer of the first germanium substrate; and
uncoupling the non-porous layer of the germanium-based material from the porous layer of the first germanium substrate thereby obtaining the germanium-based membrane and a second germanium substrate comprising porous germanium remnants including germanium crystallites.

2. The method of claim 1 wherein when said forming is performed within a vacuum environment, the first temperature ranges between 25° C. and 325° C., preferably between 100° C. and 325° C., and most preferably between 200° C. and 325° C.

3. The method of claim 1 wherein, after said forming, the porous layer of the first germanium substrate has a plurality of pore walls extending between the first germanium substrate and the non-porous layer, the pore walls having a morphology similar to an initial morphology of pore walls of the porous layer prior to said forming.

4. The method of claim 1 wherein the germanium crystallites of the porous germanium remnants have a dimension ranging between 1 nm and 19 nm.

5. The method of claim 1 further comprising removing the porous germanium remnants from the second germanium substrate.

6. The method of claim 5 wherein said removing comprise oxidizing the germanium crystallites of the porous germanium remnants using an oxidizing agent; and subsequently to said oxidizing, etching remaining porous germanium remnants using a chemically active etchant.

7. The method of claim 5 wherein said removing leaves the second germanium substrate with a surface roughness below 1 nm.

8. The method of claim 1, wherein the first germanium substrate and the second germanium substrate comprise porous germanium remnants having a porosity ranging between 40 and 80%.

9. The method of claim 1 wherein the germanium-based material is monocrystalline germanium.

10. The method of claim 1 wherein the germanium-based material is a germanium-based alloy including at least one group IV element.

11. The method of claim 1 wherein the at least one group IV element is selected from a group consisting of: silicon (Si), tin (Sn), and lead (Pb).

12. The method of claim 1 wherein the germanium-based material is doped germanium.

13. A system for manufacturing a germanium-based membrane, the system comprising:
a membrane formation device forming a non-porous layer of a germanium-based material on a porous layer of a first germanium substrate at a first temperature below a reorganization temperature of the porous layer of the first germanium substrate; and
an uncoupling device uncoupling the non-porous layer of the germanium-based material from the porous layer of the first germanium substrate thereby obtaining the germanium-based membrane and a second germanium substrate comprising porous germanium remnants including germanium crystallites.

14. The system of claim 13 wherein when said membrane formation device includes a vacuum chamber inside which said forming is performed, the first temperature ranges between 25° C. and 325° C., preferably between 100° C. and 325° C., and most preferably between 200° C. and 325° C.

15. The system of claim 13 wherein, after said forming, the porous layer of the first germanium substrate has a plurality of pore walls extending between the first germanium substrate and the non-porous layer, the pore walls having a morphology similar to an initial morphology of pore walls of the porous layer prior to said forming.

16. The system of claim 13 wherein the germanium crystallites of the porous germanium remnants have a dimension ranging between 1 nm and 19 nm.

17. The system of claim 13 further comprising a cleaning device removing porous germanium remnants from the second germanium substrate.

18. The system of claim 17 wherein the cleaning device performs a step of oxidizing the germanium crystallites of the porous germanium remnants using an oxidizing agent; and subsequently to said oxidizing, a step of etching remaining porous germanium remnants using a chemically active etchant.

19. The system of claim 13 wherein the germanium-based material is a germanium-based alloy including at least one group IV element selected from a group consisting of: silicon (Si), tin (Sn), and lead (Pb).

20. A germanium-based substrate comprising: a planar body of germanium; and a plurality of porous germanium remnants made integral to the planar body of germanium and protruding from the planar body of germanium, the porous germanium remnants comprising germanium crystallites having a dimension ranging between 1 nm and 19 nm.
